(19) United States
(12) Patent Application Publication
(10) Pub. No.: US 2026/0371912 A1
(43) Pub. Date: Nov. 19, 2026

(54) DISPLAY DEVICE INCLUDING INTERLAYER INSULATING FILM AND ELECTRONIC DEVICE COMPRISING THE SAME

(71) Applicant: SAMSUNG DISPLAY CO., LTD., YONGIN-SI (KR)

(72) Inventors: Eun Jeong JEON, Yongin-si (KR); Hyun Seok KO, Yongin-si (KR); Su Jeong KIM, Yongin-si (KR); Hye Young KIM, Yongin-si (KR); Eui Jeong KANG, Yongin-si (KR); See Ook LEE, Yongin-si (KR)

(21) Appl. No.: 19/424,659

(22) Filed: Dec. 18, 2025

(30) Foreign Application Priority Data
May 19, 2025 (KR) 10-2025-0064929
Aug. 25, 2025 (KR) 10-2025-0118473

(51) Int. Cl. H10K 59/80; H10K 59/12; H10K 59/131; H10K 59/88; H10K 102/00

(52) U.S. Cl. CPC H10K 59/8794; H10K 59/1201; H10K 59/131; H10K 59/88; H10K 2102/311

(57) ABSTRACT

A display device includes a display panel including a main region extending in a first direction and a second direction intersecting the first direction, and a sub-region protruding in the second direction from one side of the main region. An interlayer insulating film is attached to the sub-region. A package element is disposed on the interlayer insulating film. A circuit board is attached to the interlayer insulating film. The interlayer insulating film includes a package area and a general area disposed in the first direction from the package area. The package element is disposed in the package area. Each of the general area and the package area includes a circuit wiring layer electrically connecting the sub-region, the package element, and the circuit board. The general area further includes a heat sink.

### CROSS-REFERENCE TO RELATED APPLICATION

This application claims priority under 35 U.S.C. § 119 to Korean Patent Application No. 10-2025-0064929, filed in the Korean Intellectual Property Office on May 19, 2025, and to Korean Patent Application No. 10-2025-0118473, filed in the Korean Intellectual Property Office on Aug. 25, 2025, the contents of which are herein incorporated by reference in their entirety.

### TECHNICAL FIELD

The present disclosure relates to a display device and, more specifically, to a display device including an interlayer insulating film and an electronic device comprising the same.

### DISCUSSION OF THE RELATED ART

An electroluminescence display may be classified as either an inorganic light emitting display device and an organic light emitting display device, depending on a material of a light emitting layer. An active matrix type organic display device includes an organic light emitting diode (hereinafter, referred to as OLED) that emits light by itself (e.g., without the need for a separate backlight device), and has a fast response speed, high luminous efficiency, a high luminance, and a wide viewing angle. In the organic light emitting display device, the organic light emitting diode (OLED) is formed in each pixel. The organic light emitting display device has a fast response speed, excellent luminous efficiency, a high luminance, and a wide viewing angle, and also has an excellent contrast ratio and color reproducibility because pixels displaying black may look more black than on some alternative forms of display devices.

### SUMMARY

A display device includes a display panel including a main region extending in a first direction and a second direction intersecting the first direction, and a sub-region protruding in the second direction from one side of the main region. An interlayer insulating film is attached to the sub-region. A package element is disposed on the interlayer insulating film. A circuit board is attached to the interlayer insulating film. The interlayer insulating film includes a package area and a general area disposed in the first direction from the package area. The package element is disposed in the package area. Each of the general area and the package area includes a circuit wiring layer electrically connecting the sub-region, the package element, and the circuit board to each other. The general area further includes a heat sink.

The circuit wiring layer may include a first wiring layer including a first wire and a first insulating film covering the first wire.

The circuit wiring layer may further include a second wiring layer including a second wire disposed on the first insulating film and a second insulating film covering the second wire.

The heat sink may be disposed on the circuit wiring layer.

The heat sink may further include a heat dissipation plate disposed on the circuit wiring layer.

The heat sink may further include a dummy insulating film disposed on the circuit wiring layer.

The package area may further include an extension insulating film disposed in the same layer as the dummy insulating film and disposed on the circuit wiring layer.

The heat dissipation plate may be electrically isolated from the first wire in the package area.

The package area may further include an extension wire disposed in the same layer as the heat dissipation plate between the circuit wiring layer and the extension insulating film and electrically connected to the package element, and the heat dissipation plate may be electrically isolated from the extension wire.

The heat dissipation plate may include a same material as the first wire.

The extension insulating film may include a same material as the dummy insulating film.

The heat sink may further include a heat dissipation film disposed on the heat dissipation plate.

The general area may include a first general area, and a second general area disposed in the second direction from the first general area and overlapping the package element in the first direction. The package area may have a first length in the second direction. The general area may have a second length in the second direction. The first length may be equal to the second length, and the second general area may comprise a heat sink.

The heat sink may further include a metal conductor electrically connected to a heat dissipation wire disposed in a second bonding area. The heat sink may be disposed through a first through hole penetrating the first insulating film and a second through hole penetrating the second insulating film. The second bonding area may be an area where the general area and the sub-region overlap in a thickness direction of the display panel.

The metal conductor may be connected to the heat dissipation wire through the first wire.

An electronic device includes a processor configured to provide an image signal. A display module is configured to receive the image signal from the processor and display an image. A power module is configured to supply power to the display module. The display module includes a display panel including a main region extending in a first direction and a second direction intersecting the first direction, and a sub-region protruding in the second direction from one side of the main region. An interlayer insulating film is attached to the sub-region, A package element is disposed on the interlayer insulating film. A circuit board is attached to the interlayer insulating film. The interlayer insulating film includes a package area and a general area disposed in the first direction from the package area. The package element is disposed in the package area. Each of the general area and the package area includes a circuit wiring layer electrically connecting the sub-region, the package element, and the circuit board to one another. The general area further includes a heat sink.

The circuit wiring layer may include a first wiring layer including a first wire and a first insulating film covering the first wire, and a second wiring layer including a second wire disposed on the first insulating film and a second insulating film covering the second wire.

The heat sink may include a heat dissipation plate disposed on the circuit wiring layer, and a dummy insulating film disposed on the circuit wiring layer. The package area may further include an extension insulating film disposed in the same layer as the dummy insulating film and disposed on the circuit wiring layer. An extension wire may be disposed in a same layer as the heat dissipation plate between the circuit wiring layer and the extension insulating film and may be electrically connected to the package element. The heat dissipation plate may be electrically isolated from the extension wire.

The heat dissipation plate may include a same material as the first wire.

The general area may include a first general area, and a second general area disposed in the second direction from the first general area and overlapping the package element in the first direction. The package area may have a first length in the second direction. The general area may have a second length in the second direction. The first length may be equal to the second length. The second general area may include a heat sink.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing an electronic device according to an embodiment of the present disclosure;

FIG. 2 is an exploded perspective view showing the electronic device of FIG. 1 according to an embodiment of the present disclosure;

FIG. 3 is a plan view showing a display device according to an embodiment of the present disclosure;

FIG. 4 is a cross-sectional view taken along line X1-X1′ of FIG. 3;

FIG. 5 is a block diagram showing a display device according to an embodiment of the present disclosure;

FIG. 6 is a plan view showing a display device according to an embodiment of the present disclosure in an unbent state;

FIG. 7 is a plan view showing a display device according to an embodiment of the present disclosure in a bent state;

FIG. 8 is a plan view showing a comparative display device in a bent state;

FIG. 9 is a partially enlarged view showing area J of FIG. 7;

FIG. 10 is a cross-sectional view taken along line Y1-Y1′ of FIG. 9;

FIG. 11 is a cross-sectional view taken along line Y2-Y2′ of FIG. 9;

FIG. 12 is a partially enlarged view of area K of FIG. 11;

FIG. 13 is a perspective view schematically illustrating a process for manufacturing a display device according to an embodiment of the present disclosure;

FIG. 14 is a cross-sectional view taken along line Z1-Z1′ of FIG. 6;

FIG. 15 is a cross-sectional view taken along line Z2-Z2′ of FIG. 13;

FIG. 16 is a graph showing temperatures of a first bonding area and a second bonding area over time;

FIG. 17 is a plan view showing a display device according to a first embodiment of the present disclosure;

FIG. 18 is a partially enlarged view showing area L of FIG. 17;

FIG. 19 is a cross-sectional view taken along line W1-W1′ of FIG. 17;

FIG. 20 is a partially enlarged view showing area M of FIG. 19;

FIG. 21 is a partially enlarged view showing a first modified example of FIG. 20;

FIG. 22 is a partially enlarged view showing a second modified example of FIG. 20;

FIG. 23 is a partially enlarged view showing area N of FIG. 19;

FIG. 24 is a plan view showing a display device according to an embodiment of the present disclosure;

FIG. 25 is a cross-sectional view taken along line W2-W2′ of FIG. 24;

FIG. 26 is a cross-sectional view taken along line W3-W3′ of FIG. 24;

FIG. 27 is a cross-sectional view showing a first modified example of FIG. 26;

FIG. 28 is a cross-sectional view showing a second modified example of FIG. 26;

FIG. 29 is a cross-sectional view taken along line W4-W4′ of FIG. 24;

FIG. 30 is a block diagram of an electronic device according to an embodiment of the present disclosure; and

FIG. 31 is schematic view of electronic devices according to various embodiments of the present disclosure.

### DETAILED DESCRIPTION OF THE EMBODIMENTS

Aspects and features of the embodiments are disclosed herein and methods of achieving them will become apparent upon reference to the embodiments described in detail with accompanying drawings. However, the invention according to the present disclosure is not necessarily limited to the embodiments disclosed herein, but will be embodied in many different forms, and these embodiments are provided merely to make the disclosure complete and to fully inform one of ordinary skill in the art to which the invention according to the present disclosure belongs.

References to an element or layer as being “on” another element or layer include both cases in which another layer or element is directly on top of or interposed between other elements. Throughout this specification, like reference numerals may refer to like components. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Although first, second, and the like are used to describe various components, the components are not necessarily limited by these terms. Thus, a first component referred to herein may also be a second component within the technical idea of the present invention.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. To the extent that an element is not described in detail with respect to this figure, it may be understood that the element is at least similar to a corresponding element that has been described elsewhere within the present disclosure.

Embodiments of the present disclosure relate to a highly integrated flexible display device designed to enhance heat management, bonding uniformity, and overall reliability in compact electronic products. The display device may include a display panel having a main region for image display and a sub-region that protrudes from one side to accommodate a package element and circuit board. Between these components is an interlayer insulating film divided into a “package area,” which carries the package element, and a “general area,” which lies adjacent to it. The display panel and insulating film are bonded through adhesive layers, allowing the sub-region to be bent so that the package area and the circuit board overlap, enabling miniaturization of the device and freeing up additional battery space in portable applications.

This arrangement may address non-uniform heat distribution that can occur during thermocompression bonding, when the presence of a heat-dissipating package element causes uneven adhesive curing between bonding areas. This arrangement may provide a heat-dissipation structure within the general area of the interlayer insulating film to equalize temperature during manufacturing. This structure includes multilayer circuit wiring with metal wires and insulating films, a heat-dissipation plate made of a thermally conductive material such as copper, and a dummy insulating film or additional layers that balance the heat flow. By ensuring uniform curing of the adhesive across both bonding areas, the structure prevents poor adhesion and compression defects that could otherwise degrade performance or cause delamination.

The result may be a thin, flexible OLED or similar self-emissive display panel that integrates multiple semiconductor chips into a single package element, reducing circuit board size while improving thermal and mechanical reliability. The configuration not only secures additional space for larger batteries or other internal components but also maintains electrical integrity through multilayer interconnections and uniform bonding quality. Consequently, the display device may provide a robust, thermally balanced structure suitable for modern foldable, rollable, or compact electronic devices such as smartphones, tablets, and wearable displays.

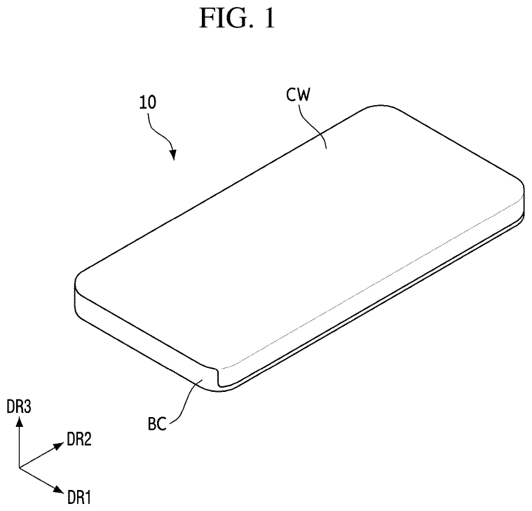

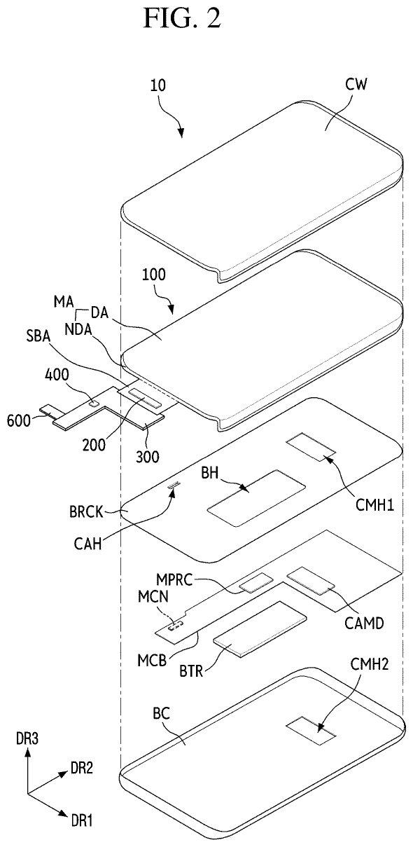

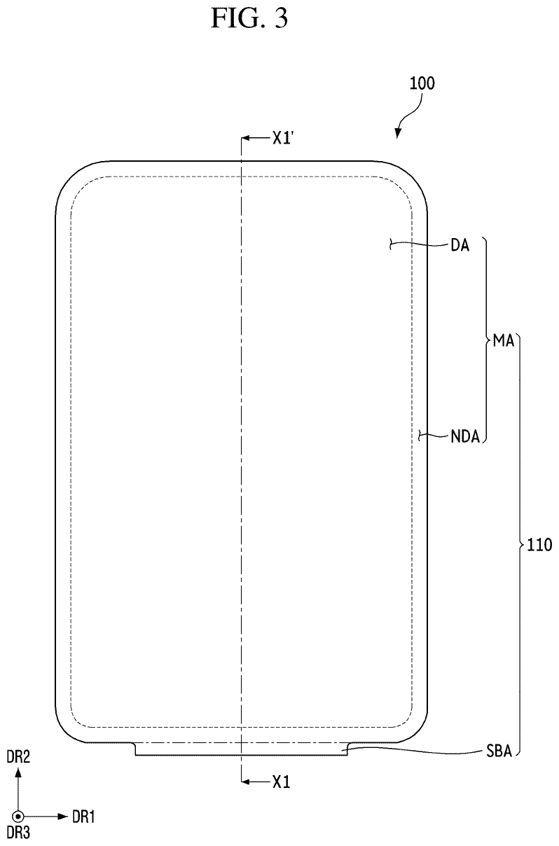

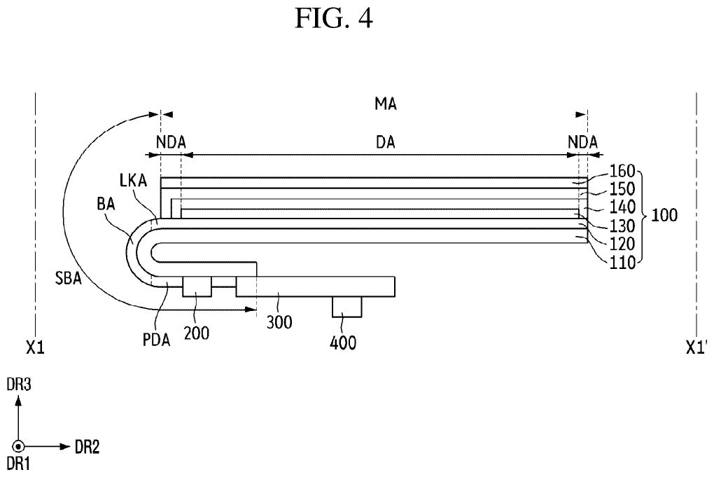

FIG. 1 is a perspective view showing an electronic device according to an embodiment of the present disclosure. FIG. 2 is an exploded perspective view showing the electronic device of FIG. 1 according to an embodiment of the present disclosure. FIG. 3 is a plan view showing a display device according to an embodiment of the present disclosure. FIG. 4 is a cross-sectional view taken along line X1-X1′ of FIG. 3.

Referring to FIGS. 1 to 4, an electronic device 10, according to an embodiment, is a device having a function of displaying an image in a display area. The electronic device 10 may be portable. For example, the electronic device 10 may be a portable electronic device such as a mobile phone, a smartphone, a tablet computer, a smart watch, a watch phone, a mobile communication terminal, an electronic notebook, an electronic book, a portable multimedia player (PMP), a navigation device and an ultra-mobile PC (UMPC). However, the electronic device 10 according to an embodiment is not necessarily limited to a portable electronic device, and may be a large-sized device such as a television, a laptop/notebook computer, a computer monitor, a digital billboard, and an Internet-of-Things (IoT) device.

The electronic device 10, according to an embodiment, may include a cover window CW and a lower cover BC, which are provided as a housing to protect a display device 100.

The electronic device 10 may further include a display device 100, a bracket BRCK, and a main circuit board MCB accommodated between the cover window CW and the lower cover BC.

The display device 100 may include a main region MA including a display area DA where an image is displayed and a non-display area NDA around the display area DA, and a sub-region SBA protruding from one side of the main region MA.

The display device 100 may further include a display driving circuit 200 disposed in the sub-region SBA, a display circuit board 300 bonded to one side of the sub-region SBA, a touch driving circuit 400 mounted on the display circuit board 300, and a cable 600 extending from one side of the display circuit board 300.

In the present disclosure, a first direction DR1 may be a direction parallel to a short side of the electronic device 10 in a plan view, for example, a horizontal direction of the electronic device 10. A second direction DR2 may be a direction parallel to a long side of the electronic device 10 in a plan view, for example, a vertical direction of the electronic device 10. A third direction DR3 (or thickness direction) may be a thickness direction of the electronic device 10.

The electronic device 10 may have a shape close to a rectangular shape in a plan view. For example, the electronic device 10 may have a rectangular shape, in a plan view, having a pair of short sides each extending in the first direction DR1 and a pair of long sides each extending in the second direction DR2. A corner where the short side in the first direction DR1 and the long side in the second direction DR2 meet may be right-angled or rounded with a selected curvature. The planar shape of the electronic device 10 is not necessarily limited to the rectangular shape, and may be formed in another polygonal shape, a circular shape or an elliptical shape.

The cover window CW may be disposed on the display device 100 to cover the top surface of the display device 100. The cover window CW may serve to protect the top surface of the display device 100.

The display device 100 may be disposed below the cover window CW. The display device 100 may include a top surface portion facing the top surface portion of the cover window CW, a left surface portion facing the left surface portion of the cover window CW, and a right surface portion facing the right surface portion of the cover window CW. The left surface portion of the display device 100 may extend from the left side of the top surface portion, and the right surface portion of the display device 100 may extend from the right side of the top surface portion.

The display device 100 may include the main region MA serving as a display surface and the sub-region SBA protruding from at least a part of one side of the main region MA.

The main region MA may include the display area DA displaying an image and the non-display area NDA that is a peripheral area of the display area DA. The non-display area NDA may be disposed outside the display area DA. The non-display area NDA may be an edge area of the main region MA.

The sub-region SBA may protrude from one side of the main region MA in the second direction DR2. The length of the sub-region SBA in the first direction DR1 may be less than or equal to the length of the main region MA in the first direction DR1. The length of the sub-region SBA in the second direction DR2 may be less than the length of the main region MA in the second direction DR2, but is not necessarily limited thereto.

Since a part of the sub-region SBA is transformed to be bent, another part of the sub-region SBA may overlap the main region MA in the third direction DR3 (or thickness direction). The display driving circuit 200 may be mounted on the sub-region SBA, and the display circuit board 300 may be attached to the sub-region SBA.

One end of the display circuit board 300 may be attached to pads disposed at the lower edge of the sub-region SBA of the display device 100 by using an anisotropic conductive film. The anisotropic conductive film may extend in the first direction DR1.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

The display driving circuit 200 may output data signals of data lines of a circuit layer disposed in the display area DA based on control signals, powers, and voltages supplied through the display circuit board 300. The data signals may be transmitted to light emitting pixel drivers through the data lines.

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and an embodiment is not necessarily limited thereto. For example, the display driving circuit 200 may be mounted on the display circuit board 300.

According to an embodiment, the touch driving circuit 400 may be further mounted on the sub-region SBA of the display device 100. The touch driving circuit 400 may be mounted on the display circuit board 300. The touch driving circuit 400 may be electrically connected to the touch sensor layer of the display device 100.

The bracket BRCK may be disposed under the display device 100. The bracket BRCK may include plastic or metal. The bracket BRCK may include a first camera hole CMH1 into which a camera device CAMD is inserted, a battery hole BH into which a battery BTR is disposed, and a cable hole CAH through which the cable 600 connected to the display circuit board 300 passes. The main circuit board MCB and the battery BTR may be disposed under the bracket BRCK.

The main circuit board MCB may be a printed circuit board or a flexible printed circuit board. The main circuit board MCB may include a main processor MPRC, the camera device CAMD, and a main connector MCN. The main processor MPRC may be formed as an integrated circuit. The main processor MPRC may control all functions of the electronic device 10. For example, the main processor MPRC may output digital video data to the display driving circuit 200 through the display circuit board 300 such that the display device 100 displays an image. In addition, the main processor MPRC may receive touch data including user's touch coordinates from the touch driving circuit 400, determine whether or not the user has touched or approached, and then perform an operation corresponding to the user's touch input or approach input. For example, the main processor MPRC may perform an operation or execute an application indicated by an icon touched by the user. The main processor MPRC may be an application processor formed as an integrated circuit, a central processing unit, or a system chip. In addition, the main circuit board MCB may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The camera device CAMD may be disposed on both the top surface and the bottom surface of the main circuit board MCB, the main processor MPRC may be disposed on the top surface of the main circuit board MCB, and the main connector MCN may be disposed on the bottom surface of the main circuit board MCB. The camera device CAMD processes an image frame of a still image or video obtained by an image sensor in a camera mode and outputs it to the main processor MPRC.

The cable 600 having passed through the cable hole CAH of the bracket BRCK may be connected to the main connector MCN. Thus, the main circuit board MCB may be electrically connected to the display circuit board 300.

The battery BTR may be disposed so as not to overlap the main circuit board MCB in the third direction DR3 (or thickness direction). The battery BTR may overlap the battery hole BH of the bracket BRCK in the third direction DR3 (or thickness direction).

The lower cover BC may be disposed below the main circuit board MCB and the battery BTR. The lower cover BC may be fixed by being fastened to the bracket BRCK. The lower cover BC may form the upper side surface, lower side surface, and bottom surface of the electronic device 10. The lower cover BC may include plastic, metal, or both plastic and metal. The lower cover BC may include a second camera hole CMH2 through which the bottom surface of the camera device CAMD is exposed. The position of the camera device CAMD and the positions of the first camera hole CMH1 and the second camera hole CMH2 corresponding to the camera device CAMD are not necessarily limited by those illustrated.

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not necessarily limited thereto, and may be applied to a display device including an organic insulating material, an organic light emitting material, and a metal material.

The display device 100 may be flat, but is not necessarily limited thereto. For example, the display device 100 may include a curved portion formed at left and right ends and having a constant curvature or a varying curvature. In addition, the display device 100 may be flexible so that it can be curved, bent, folded, or rolled to at least a noticeable extent without cracking or otherwise sustaining damage thereto.

The sub-region SBA may include a bending area BA transformed into a bent shape, a link area LKA disposed between one side of the bending area BA and the main region MA, and a pad area PDA connected to the other side of the bending area BA. When the bending area BA is transformed into a bent shape, the pad area PDA may be disposed on the rear surface of the display device 100 and may overlap the main region MA in the third direction DR3 (or thickness direction).

According to an embodiment, the display device 100 may include a substrate 110, a circuit layer 120 disposed on the substrate 110, an element layer 130 disposed on the circuit layer 120, and an encapsulation layer 140 disposed on the element layer 130. The display device 100 may further include a touch sensor layer 150 disposed on the encapsulation layer 140. The display device 100 may further include a polarization layer 160 disposed on the touch sensor layer 150, in order to reduce reflection of external light.

The display area DA may include emission areas that emit light, and a non-emission area disposed between the emission areas.

The circuit layer 120 may include light emitting pixel drivers EPD electrically connected to the light emitting elements, and data lines transmitting data signals to the light emitting pixel drivers EPD. The element layer 130 may include light emitting elements respectively disposed in the emission areas. The encapsulation layer 140 may cover the element layer 130. The encapsulation layer 140 may include a structure in which two or more inorganic films and at least one organic film are alternately stacked. The touch sensor layer 150 may be disposed on the encapsulation layer 140 and may correspond to the main region MA. The touch sensor layer 150 may include touch electrodes for sensing a touch of a person or an object. The polarization layer 160 blocks external light reflected from the touch sensor layer 150, the encapsulation layer 140, the element layer 130, and the circuit layer 120, and the interfaces thereof, and this is to prevent the deterioration of visibility of an image due to external light reflection.

The display driving circuit 200 may be mounted on the pad area PDA of the sub-region SBA of the substrate 110.

The display circuit board 300 may be connected to pads arranged in the pad area PDA in the sub-region SBA of the substrate 110. When the bending area BA is transformed into a bent shape, the display driving circuit 200 and the display circuit board 300 may be placed under the substrate 110.

The display driving circuit 200 may be electrically connected to the data lines through data supply lines. The display driving circuit 200 may output the data signals of the light emitting pixel drivers to the data lines DL based on control signals and power voltages supplied from the display circuit board 300. One end of the display circuit board 300 may be attached and connected to the pads using an anisotropic conductive film.

The touch driving circuit 400 may be mounted on the display circuit board 300. The touch driving circuit 400 may be electrically connected to the touch sensor layer 150 of the display device 100. The touch driving circuit 400 may apply a touch driving signal to driving lines of the touch sensor layer 150, and receive a touch sensing signal from sensing lines. Further, the touch driving circuit 400 may detect charge variation amounts of capacitances based on the touch sensing signal, thereby determining whether a user has touched or approached.

The display circuit board 300 may be attached and connected to the pads. The pads may include data pads electrically connected to the display driving circuit 200 and constant voltage transfer pads transmitting a constant voltage.

Thus, the device may include a display panel with a main display region and a protruding sub-region that carries a display driving circuit, touch driving circuit, and a circuit board connected through an anisotropic conductive film. The display may be protected by a cover window and supported by a bracket housing the main circuit board, processor, battery, and camera, while layers such as the encapsulation, touch sensor, and polarization layers enable high-quality image display, touch responsiveness, and reduced reflection in a compact, bendable configuration.

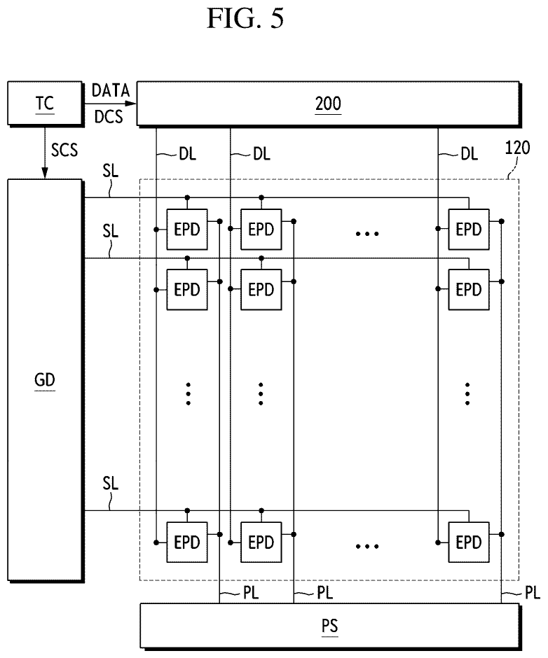

FIG. 5 is a block diagram showing a display device according to an embodiment of the present disclosure.

Referring to FIG. 5, the circuit layer 120 of a display device, according to an embodiment, may include the light emitting pixel drivers EPD electrically connected to light emitting elements of the element layer, and the data lines DL transmitting data signals to the light emitting pixel drivers EPD.

The circuit layer 120 may further include one or more scan lines SL that transmit one or more scan signals to the light emitting pixel drivers EPD.

According to an embodiment, the display device may further include the display driving circuit 200 that outputs data signals corresponding to the luminances of the respective light emitting elements to the data lines DL.

According to an embodiment, the display device 10 may further include a scan driver GD that outputs scan signals to the gate lines GL, a power supply unit PS that supplies power and voltages to the light emitting pixel drivers EPD, and a timing controller TC that controls the driving timing of each of the display driving circuit 200 and the gate driver GD.

The timing controller TC receives an image signal supplied from a source external to the display device. The timing controller TC may output image data DATA and a data control signal DCS to the display driving circuit 200. The timing controller TC may generate the scan control signal SCS for controlling the operation timing of the gate driver GD.

The display driving circuit 200 may convert the image data DATA into analog data voltages and output them to the data lines DL.

The gate driver GD may generate scan signals in response to the scan control signal SCS and sequentially output the scan signals to the scan lines SL. The scan signals may have pulses that vary to a first gate level voltage or a second gate level voltage.

The power supply unit PS may supply various power and voltages necessary for driving the light emitting pixel drivers EPD. For example, the power supply unit PS may supply constant voltages such as a first power and a second power for generating driving signals of the light emitting elements, a gate initialization voltage and a bias voltage for initializing the light emitting pixel drivers EPD, and an anode initialization voltage for initializing the light emitting elements.

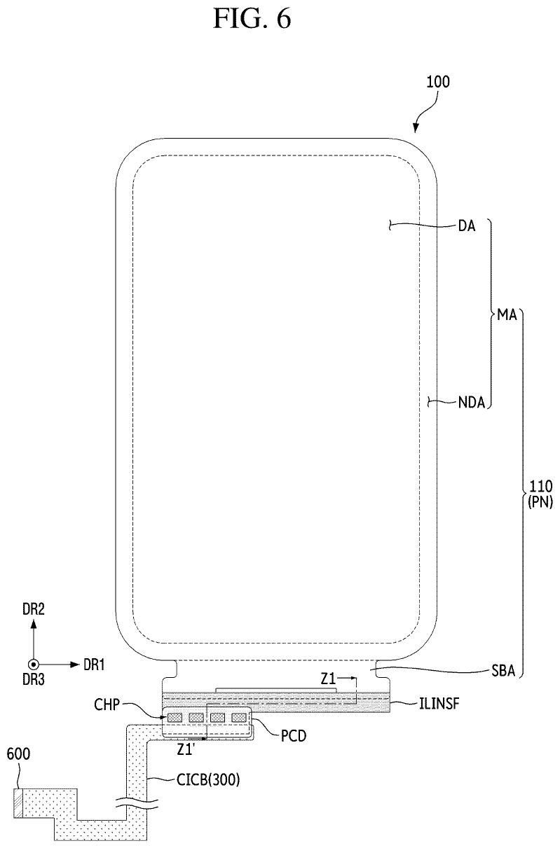

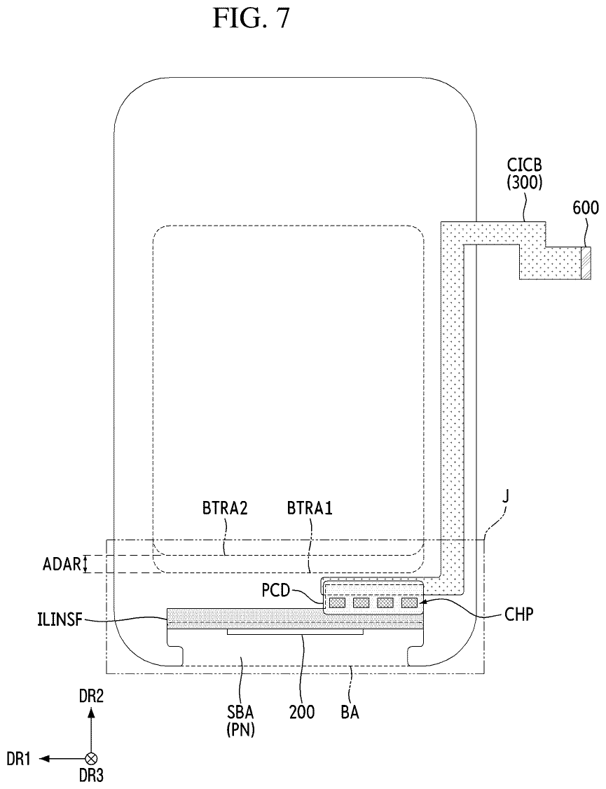

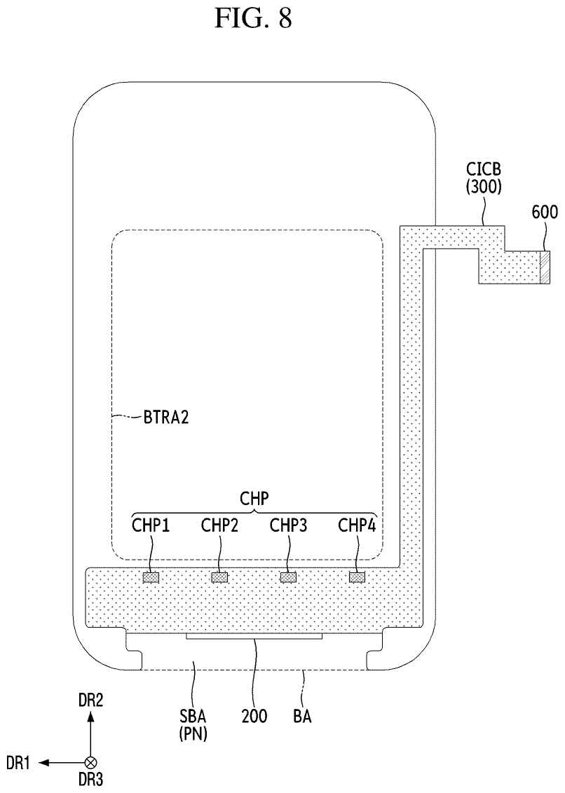

FIG. 6 is a plan view showing a display device according to an embodiment of the present disclosure in an unbent state. FIG. 7 is a plan view showing a display device according to an embodiment of the present disclosure in a bent state. FIG. 8 is a plan view showing a comparative display device in a bent state.

Referring to FIGS. 6 to 8, a display device according to an embodiment of the present disclosure may include a display panel PN, the display driving circuit 200, an interlayer insulating film ILINSF, a package element PCD, a circuit board CICB (or the display circuit board 300), and a connector 600. The display panel PN may include the main region MA and the sub-region SBA. The main region MA may include the display area DA and the non-display area NDA.

The display panel PN may be electrically connected to the package element PCD and the circuit board CICB (or the display circuit board 300) through the interlayer insulating film ILINSF. The interlayer insulating film ILINSF may be attached to the sub-region SBA of the display panel PN through bonding areas BONA1 and BONA2. The interlayer insulating film ILINSF may be electrically connected to the package element PCD and the circuit board CICB (or the display circuit board 300).

The package element PCD may include a plurality of chips CHP. The package element PCD may be implemented by integrating multiple semiconductor chips CHP into a single package. A complex system including the plurality of chips CHP may be implemented in a single compact package through the package element PCD.

For example, the package element PCD may include the plurality of chips CHP mounted on a comparative circuit board CICB (or the display circuit board 300). The plurality of chips CHP may include, e.g., a first chip CHP1, a second chip CHP2, a third chip CHP3, and a fourth chip CHP4. However, the number of chips CHP is not necessarily limited thereto. For example, the first chip CHP1 may be a touch driving circuit. The second chip CHP2 may be an analog-to-digital converter ADC. The third chip CHP3 may be a microcontroller unit MCU. The fourth chip CHP4 may be a memory chip CHP (e.g., flash memory or the like), or a power management integrated circuit PMIC. In addition to the examples described above, the plurality of chips CHP may further include an interface chip CHP, a security chip CHP, a sensor correction and calibration integrated circuit, and the like, and the examples of the chip CHP are not necessarily limited thereto.

Implementing a system within a single package, such as the package element PCD, may be referred to as system in package (SiP). In the case of implementing the system in package, such as the package element PCD, various functions are integrated into a single compact package, so that it is possible to save space or reduce signal interference, and, in some cases, it is possible to perform optimized power management.

In a comparative display device, the space for the circuit board CICB (or the display circuit board 300) is relatively large, and the plurality of chips CHP are distributed and arranged in the relatively large space for the circuit board CICB (or the display circuit board 300). They may be connected to the display panel PN through an external line of the circuit board CICB. The comparative circuit board CICB (or the display circuit board 300) is advantageous in that it is relatively simple in terms of manufacturing complexity and it is relatively easy to replace individual components. However, the comparative circuit board CICB is disadvantageous in that it is difficult to secure a battery capacity due to a relatively large size. For example, the comparative display device may have a second battery area BTRA2.

A display device according to an embodiment of the present disclosure includes the package element PCD, and electrically connects the package element PCD, the display panel PN, and the circuit board CICB (or the display circuit board 300) to each other through the interlayer insulating film ILINSF. In the case of implementing a complex system through a single package element PCD, it is advantageous in that the circuit board CICB (or the display circuit board 300) may be miniaturized and, in particular, a space for physically locating a battery may be further secured. For example, a display device according to an embodiment may include a first battery area BTRA1.

The first battery area BTRA1 further has an additional battery area ADAR compared to the second battery area BTRA2. Due to the additional battery area ADAR, it is possible to further secure a space for locating the battery physically, thereby improving the operating time of the display device. Further, the activation of a high-performance function and the thermal management of the display device may be facilitated.

A display device according to an embodiment of the present disclosure implements a structure in which the plurality of chips CHP are densely packed in a single package through the package element PCD including the plurality of chips CHP. Accordingly, the physical size of the circuit board CICB (or the display circuit board 300) may be reduced, and the additional battery area ADAR may be secured.

If the display device includes the package element PCD, a display device according to an embodiment may further include the interlayer insulating film ILINSF electrically connected to the package element PCD. The interlayer insulating film ILINSF may be electrically connected to the circuit board CICB (or the display circuit board 300) and the display panel PN.

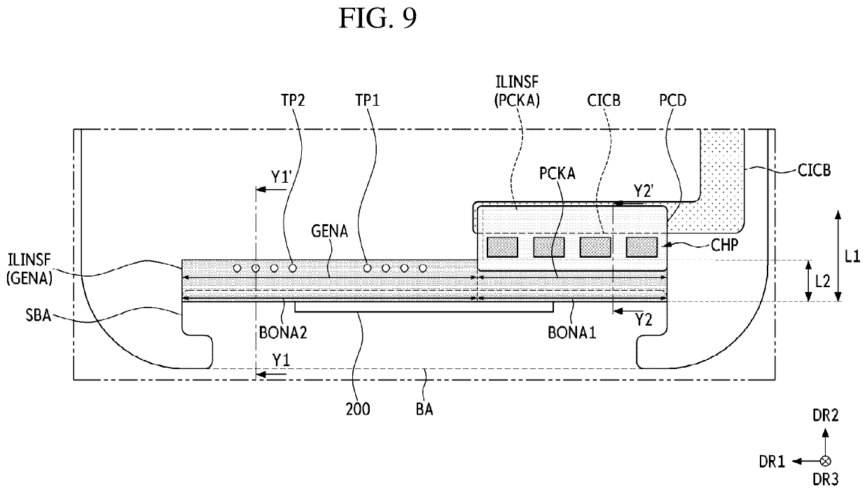

FIG. 9 is a partially enlarged view showing area J of FIG. 7.

Referring to FIG. 9 in a bent shape, the sub-region SBA may be connected to the interlayer insulating film ILINSF through the bonding areas BONA1 and BONA2. The bonding areas BONA1 and BONA2 may be areas where the sub-region SBA and the interlayer insulating film ILINSF overlap in the third direction DR3 (or thickness direction).

The interlayer insulating film ILINSF may be divided into a plurality of areas. The interlayer insulating film ILINSF may include a plurality of areas extending in the first direction DR1 and the second direction DR2. The interlayer insulating film ILINSF may include a package area PCKA extending in the first direction DR1 and the second direction DR2, and a general area GENA disposed in the first direction DR1 from the package area PCKA.

The area where the package area PCKA and the sub-region SBA overlap in the third direction DR3 (or thickness direction) may be the first bonding area BONA1. The area where the general area GENA and the sub-region SBA overlap in the third direction DR3 (or thickness direction) may be the second bonding area BONA2. The package area PCKA may be electrically connected to the sub-region SBA through the first bonding area BONA1, and the general area GENA may be electrically connected to the sub-region SBA through the second bonding area BONA2.

The package element PCD may be mounted or disposed in the package area PCKA. The package area PCKA may be distinguished from the general area GENA in that the package element PCD is included. The circuit board CICB may further be connected to the package area PCKA.

In an embodiment, the general area GENA may be formed to extend in the first direction DR1. The package area PCKA may extend in the first direction DR1 and then extend to protrude in the second direction DR2. Since the package area PCKA includes the package element PCD, the package area PCKA may include a bent portion, but the embodiments of the present disclosure are not necessarily limited thereto. Depending on the size of the interlayer insulating film ILINSF, the package element PCD, and the circuit board CICB, the overlapping, protruding relationships, or shapes thereof may vary.

The package area PCKA may have a first length L1 in the second direction DR2, and the general area GENA may have a second length L2 in the second direction DR2. The second length L2 may be the same as or different from the first length L1. In an embodiment, the second length L2 may be less than the first length L1. Accordingly, the package area PCKA may have a shape protruding in the second direction DR2, or in a direction in which the circuit board CICB is disposed. The circuit board CICB may be attached to the protruding shape. For example, the protruding shape of the interlayer insulating film ILINSF may be disposed between the circuit board CICB and the package element PCD in the third direction DR3 (or thickness direction).

The general area GENA may include a plurality of test pads TP1 and TP2. The test pads TP1 and TP2 may include a first test pad TP1 and a second test pad TP2 disposed to be spaced apart from the first test pad TP1. The test pads TP1 and TP2 may be used to evaluate the assembly reliability between the interlayer insulating film ILINSF, the package element PCD, the sub-region SBA, and the circuit board CICB. For example, the test pads TP1 and TP2 may be portions to be in contact with external probes (probe pins) to evaluate adhesive quality, contact stability, and durability against heat and/or humidity after the interlayer insulating film ILINSF, the package element PCD, and the circuit board CICB are assembled to be electrically connected. By positioning the test pads TP1 and TP2, it is possible to predict deterioration and failure of the display device, and perform an environmental stress test, thereby facilitating the quality control of the display device.

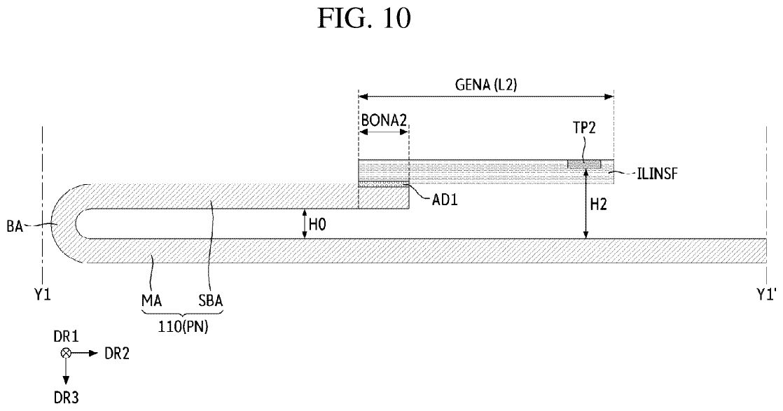

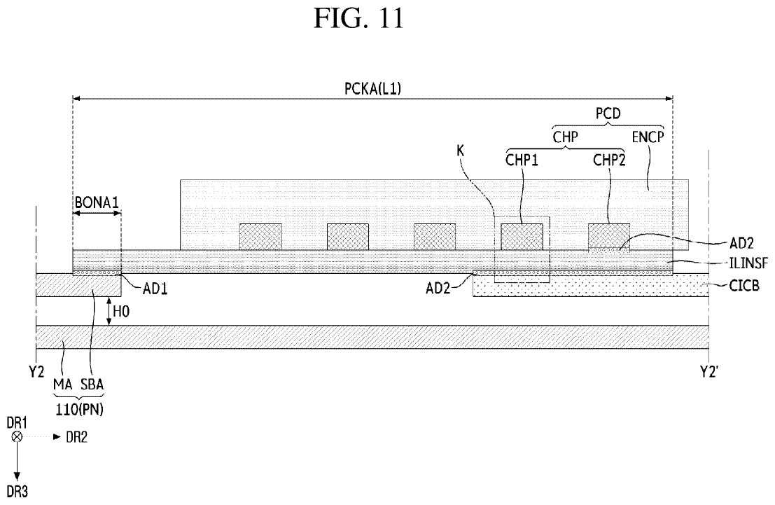

FIG. 10 is a cross-sectional view taken along line Y1-Y1′ of FIG. 9. FIG. 11 is a cross-sectional view taken along line Y2-Y2′ of FIG. 9.

Referring to FIGS. 9 and 10, in a bent shape, the display panel PN may include the main region MA, the sub-region SBA, and the bending area BA that connects the main region MA and the sub-region SBA. A support member that is in contact with and supports both the sub-region SBA and the main region MA may be further disposed in a separation space corresponding to a distance H0 between the main region MA and the sub-region SBA.

The sub-region SBA may be electrically connected to the interlayer insulating film ILINSF through a first adhesive member AD1. The illustrated cross-sectional views show a portion of the interlayer insulating film ILINSF that corresponds to the general area GENA, so that the length of the interlayer insulating film ILINSF in the second direction DR2 may be the second length L2. The first adhesive member AD1 may include an anisotropic conductive film (ACF). The first adhesive member AD1 may be disposed in the second bonding area BONA2 to fix the interlayer insulating film ILINSF in the sub-region SBA.

The second test pad TP2 may be spaced apart from the main region MA by a distance corresponding to a second height H2. Although not illustrated, the first test pad TP1 may be spaced apart from the main region MA by a distance corresponding to a first height. In an embodiment, the first height and the second height H2 may be the same. In the display device according to the embodiments of the present disclosure, the first test pad TP1 and the second test pad TP2 may be disposed at the same distance from the main region MA.

When the first test pad TP1 and the second test pad TP2 are positioned at different heights, as in the case where the first test pad TP1 is disposed in the second bonding area BONA2, errors in an assembly reliability test (ART) may occur due to the stepped portion between the first test pad TP1 and the second test pad TP2. The display device according to the embodiment includes the first test pad TP1 and the second test pad TP2 formed at the same height, so that the accuracy of the assembly reliability test may be improved.

Referring to FIGS. 9 and 11, the sub-region SBA may be electrically connected to the interlayer insulating film ILINSF through the first adhesive member AD1. The illustrated cross-sectional views show a portion of the interlayer insulating film ILINSF that corresponds to the package area PCKA, so that the length of the interlayer insulating film ILINSF in the second direction DR2 may be the first length L1. The first adhesive member AD1 may include an anisotropic conductive film (ACF). The first adhesive member AD1 may be disposed in the first bonding area BONA1 to fix the interlayer insulating film ILINSF in the sub-region SBA.

The package element PCD may be disposed in the package area PCKA of the interlayer insulating film ILINSF. The package element PCD may be disposed on the interlayer insulating film ILINSF. The package element PCD may be disposed on one surface of the interlayer insulating film ILINSF, and the circuit board CICB may be attached to the other surface of the interlayer insulating film ILINSF. For example, the interlayer insulating film ILINSF may be disposed between the package element PCD and the circuit board CICB in the third direction DR3 (or thickness direction).

The circuit board CICB may be electrically connected to the interlayer insulating film ILINSF through a second adhesive member AD2. The circuit board CICB may be attached to the interlayer insulating film ILINSF through the second adhesive member AD2. The second adhesive member AD2 may include metal, but the embodiments of the present disclosure are not necessarily limited thereto. In an embodiment, the metal may include tin (Sn) and lead (Pb) or lead-free solder (Sn—Ag—Cu), but the embodiments of the present disclosure are not necessarily limited thereto. For example, the interlayer insulating film ILINSF and the circuit board CICB may be connected to each other by soldering. The soldering may be an adhesion method of connecting the interlayer insulating film ILINSF and the circuit board CICB to each other by melting metal. For example, the circuit board CICB may be connected to the interlayer insulating film ILINSF by soldering.

The package element PCD disposed on one surface of the interlayer insulating film ILINSF may include the plurality of chips CHP and an encapsulant ENCP. The plurality of chips CHP may include the first chip CHP1 and the second chip CHP2, and the embodiments of the present disclosure are not necessarily limited thereto. Further, the examples of the first chip CHP1 and the second chip CHP2 are not necessarily limited to those described above.

Any one chip CHP (e.g., the second chip CHP2) of the package element PCD may be connected to the interlayer insulating film ILINSF through the second adhesive member AD2, and another chip CHP (e.g., the first chip CHP1) may be electrically connected to the interlayer insulating film ILINSF by another connection method.

The encapsulant ENCP may be a component formed to encapsulate and fix the plurality of chips CHP. The encapsulant ENCP may serve to protect the plurality of chips CHP from external environment such as dust, moisture, and impact, perform a heat dissipation function by transmitting heat emitted during the operation of the chip CHP to the ambient environment, prevent electrical interference between the chip CHP and the ambient environment, and mechanically support the plurality of chips CHP at the interlayer insulating film ILINSF.

For example, the encapsulant ENCP may be an epoxy-based encapsulant. For example, the encapsulant ENCP may be an epoxy molding compound (EMC). The encapsulant ENCP may include an epoxy resin that is a thermosetting polymer, a filler for improving thermal conductivity and mechanical strength, a curing agent for curing the epoxy resin, and an additive for controlling adhesive strength, fluidity, moisture resistance, and the like.

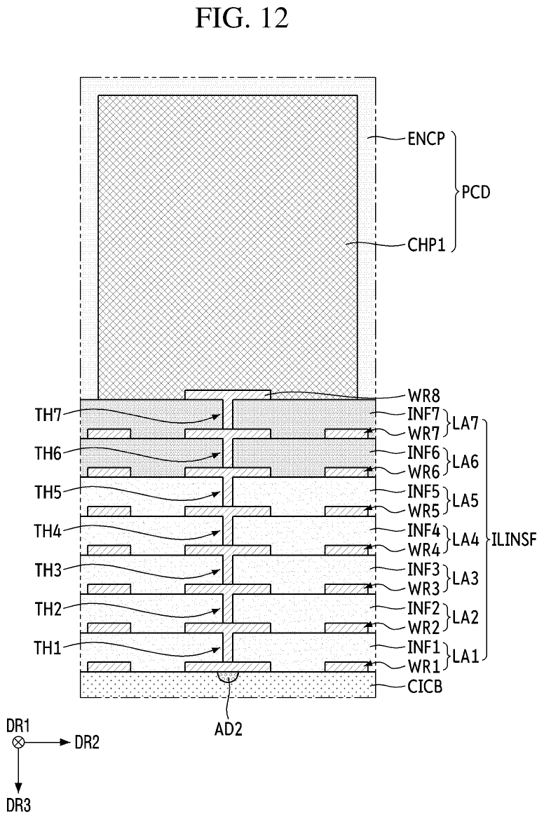

FIG. 12 is a partially enlarged view of area K of FIG. 11.

Referring to FIGS. 11 and 12, the interlayer insulating film ILINSF may be electrically connected to the circuit board CICB through the second adhesive member AD2. The package element PCD may be disposed on the interlayer insulating film ILINSF, and the first chip CHP1 according to embodiments may be electrically connected to the interlayer insulating film ILINSF by another connection method described above.

The interlayer insulating film ILINSF may include circuit wiring layers LA1, LA2, LA3, LA4, LA5, LA6, and LA7 including a plurality of wiring layers LA1, LA2, LA3, LA4, LA5, LA6, and LA7. The circuit wiring layers LA1, LA2, LA3, LA4, LA5, LA6, and LA7 may include the plurality of wiring layers LA1, LA2, LA3, LA4, LA5, LA6, and LA7 for electrically connecting the sub-region SBA to the package element PCD, or the sub-region SBA to the circuit board CICB. The plurality of wiring layers LA1, LA2, LA3, LA4, LA5, LA6, and LA7 may include a first wiring layer LA1, a second wiring layer LA2, a third wiring layer LA3, a fourth wiring layer LA4, a fifth wiring layer LA5, a sixth wiring layer LA6, and a seventh wiring layer LA7, but the embodiments of the present disclosure are not necessarily limited thereto.

The plurality of wiring layers LA1, LA2, LA3, LA4, LA5, LA6, and LA7 may include wires WR1, WR2, WR3, WR4, WR5, WR6, and WR7 and insulating films INF1, INF2, INF3, INF4, INF5, INF6, and INF7 covering the wires WR1, WR2, WR3, WR4, WR5, WR6, and WR7, respectively. For example, the first wiring layer LA1 may include the first wire WR1 and the first insulating film INF1 covering the first wire WR1, the second wiring layer LA2 may include the second wire WR2 and the second insulating film INF2 covering the second wire WR2, the third wiring layer LA3 may include the third wire WR3 and the third insulating film INF3 covering the third wire WR3, the fourth wiring layer LA4 may include the fourth wire WR4 and the fourth insulating film INF4 covering the fourth wire WR4, the fifth wiring layer LA5 may include the fifth wire WR5 and the fifth insulating film INF5 covering the fifth wire WR5, the sixth wiring layer LA6 may include the sixth wire WR6 and the sixth insulating film INF6 covering the sixth wire WR6, and the seventh wiring layer LA7 may include the seventh wire WR7 and the seventh insulating film INF7 covering the seventh wire WR7. In this way, the circuit wiring layers LA1, LA2, LA3, LA4, LA5, LA6, and LA7 may be formed in a structure in which multiple layers of wires and insulating films are repeatedly stacked to implement a highly integrated circuit.

Each of the plurality of wires WR1, WR2, WR3, WR4, WR5, WR6, and WR7 may include metal. For example, the plurality of wires WR1, WR2, WR3, WR4, WR5, WR6, and WR7 may include copper. The plurality of wires WR1, WR2, WR3, WR4, WR5, WR6, and WR7 may serve to transmit an electrical signal in the circuit wiring layers LA1, LA2, LA3, LA4, LA5, LA6, and LA7.

Each of the plurality of insulating films INF1, INF2, INF3, INF4, INF5, INF6, and INF7 may include an epoxy resin-based insulating material. Each of the plurality of insulating films INF1, INF2, INF3, INF4, INF5, INF6, and INF7 may serve to prevent electrical interference between the plurality of wires WR1, WR2, WR3, WR4, WR5, WR6, and WR7 and prevent a leakage current.

Although the plurality of insulating films INF1, INF2, INF3, INF4, INF5, INF6, and INF7 include a common material because they all include an epoxy-based insulating material, they may be divided into two groups of layers including different materials. In an embodiment, the first insulating film INF1, the second insulating film INF2, the third insulating film INF3, the fourth insulating film INF4, and the fifth insulating film INF5 may include the same material, and the sixth insulating film INF6 and the seventh insulating film INF7 may include the same material. For example, the first insulating film INF1, the second insulating film INF2, the third insulating film INF3, the fourth insulating film INF4, and the fifth insulating film INF5 may include an epoxy-based resin, a curing agent, and inorganic fine particles. The sixth insulating film INF6 and the seventh insulating film INF7 may include an epoxy-based resin and glass fiber. The sixth insulating film INF6 and the seventh insulating film INF7 may include a pre-impregnated composite (prepreg). Prepreg is cured in response to heat and pressure, and has excellent mechanical strength and electrical characteristics.

Through holes TH1, TH2, TH3, TH4, TH5, TH6, and TH7 may be formed in the plurality of insulating films INF1, INF2, INF3, INF4, INF5, INF6, and INF7, respectively. For example, a first through hole TH1 may be formed in the first insulating film INF1, a second through hole TH2 may be formed in the second insulating film INF2, a third through hole TH3 may be formed in the third insulating film INF3, a fourth through hole TH4 may be formed in the fourth insulating film INF4, a fifth through hole TH5 may be formed in the fifth insulating film INF5, a sixth through hole TH6 may be formed in the sixth insulating film INF6, and a seventh through hole TH7 may be formed in the seventh insulating film INF7.

The plurality of wires WR1, WR2, WR3, WR4, WR5, WR6, and WR7 may be electrically connected to each other through the through holes TH1, TH2, TH3, TH4, TH5, TH6, and TH7 formed in the plurality of insulating films INF1, INF2, INF3, INF4, INF5, INF6, and INF7, respectively. An eighth wire WR8 may be further disposed on the seventh wiring layer LA7. The eighth wire WR8 may electrically connect the package element PCD including the first chip CHP1 to the interlayer insulating film ILINSF.

Thus, a display system may include a timing controller that coordinates the driving circuit, gate driver, and power supply to deliver image, scan, and power signals to pixel drivers that light up each display element. The design may integrate multiple semiconductor chips within a single package element mounted on an interlayer insulating film that connects the display panel and circuit board, minimizing space and improving power and thermal efficiency. The interlayer film may include multilayer copper wiring, epoxy insulating films, through-holes, and test pads at uniform height for accurate assembly testing and reliable electrical connections.

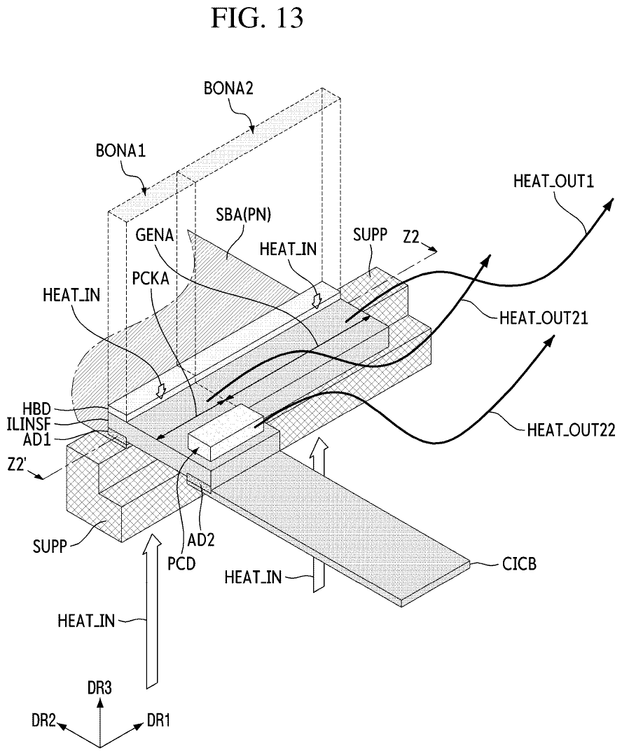

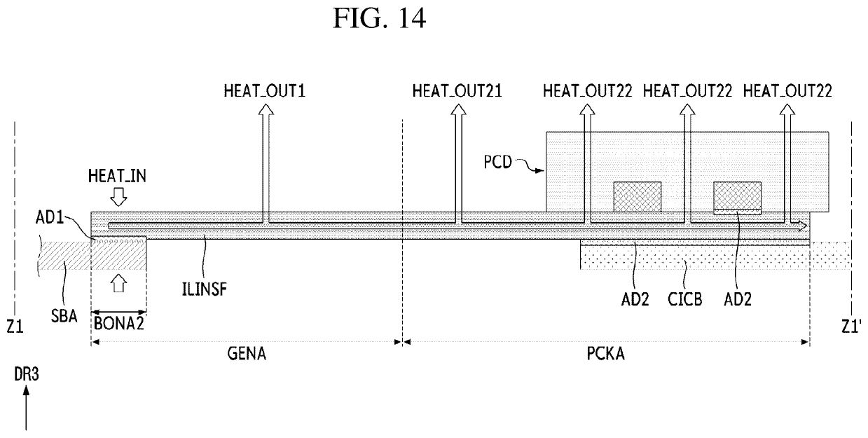

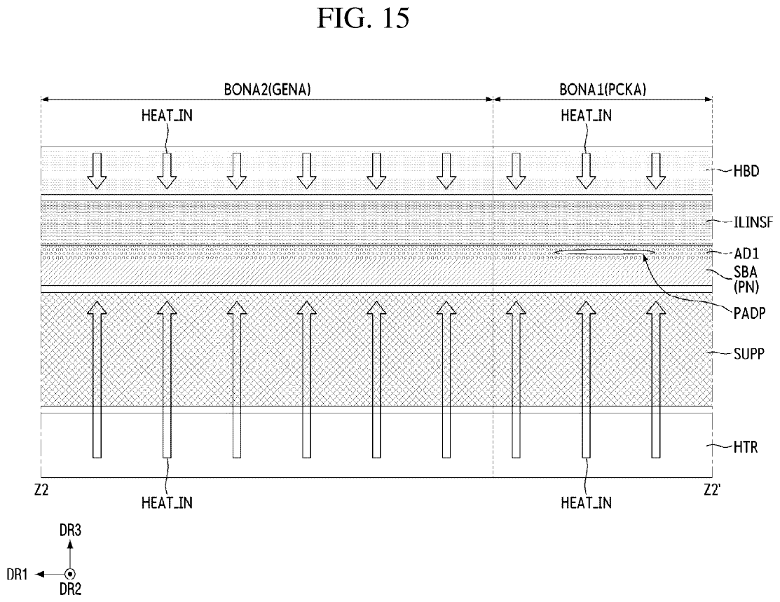

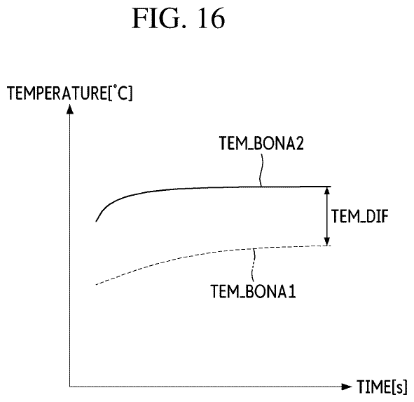

FIG. 13 is a perspective view schematically illustrating a process for manufacturing a display device according to an embodiment of the present disclosure. FIG. 14 is a cross-sectional view taken along line Z1-Z1′ of FIG. 6. FIG. 15 is a cross-sectional view taken along line Z2-Z2′ of FIG. 13. FIG. 16 is a graph showing temperatures of a first bonding area and a second bonding area over time.

Referring to FIGS. 13 to 16, the interlayer insulating film ILINSF to which the circuit board CICB and the package element PCD are attached may be bonded to the sub-region SBA by a thermocompression process. The thermocompression process between the interlayer insulating film ILINSF and the sub-region SBA may be performed by a manufacturing apparatus including a heater HTR, a support plate SUPP, and a heat bonding device HBD. The heater HTR and the heat bonding device HBD supply heat to the first adhesive member AD1 between the sub-region SBA and the interlayer insulating film ILINSF, and the heat bonding device HBD applies pressure to the display panel PN and the interlayer insulating film ILINSF disposed on the support plate.

The conductive particles in the first adhesive member AD1 (or conductive particles in an anisotropic conductive film) may be connected between the interlayer insulating film ILINSF and the display panel PN by supply heat HEAT_IN supplied by the heat bonding device HBD to the first bonding area BONA1 and the second bonding area BONA2 and supply heat HEAT_IN transferred by the heater HTR to the first bonding area BONA1 and the second bonding area BONA2 through the support plate SUPP on the side where the support plate SUPP is disposed.

When the interlayer insulating film ILINSF and the display panel PN are bonded by the manufacturing apparatus, heat greater than a threshold amount needs to be supplied to the first adhesive member AD1. When heat is supplied to the display device, the temperature of the heat bonding device HBD may be higher than the temperature of the support plate SUPP.

As described above, the interlayer insulating film ILINSF may include the general area GENA and the package area PCKA. The length of the general area GENA in the second direction DR2 may be less than the length of the package area PCKA in the second direction DR2. The package element PCD may be disposed in the package area PCKA. In the interlayer insulating film ILINSF, the general area GENA and the package area PCKA may emit heat in response to the supply heat HEAT_IN. The general area GENA may emit first emission heat HEAT_OUT1, and the package area PCKA may emit second emission heat HEAT_OUT21 and third emission heat HEAT_OUT22.

The package element PCD may be disposed in the package area PCKA, and the package element PCD may perform a function of a heat dissipation plate (heat sink) HDP when heat is supplied to the display device. In an embodiment, the surface heat loss rate (W/m²) of the package element PCD may be greater than that of the interlayer insulating film ILINSF.

Accordingly, the first adhesive member AD1 (or anisotropic conductive film) of the first bonding area BONA1 may not sufficiently receive heat. For example, the supply heat HEAT_IN transferred to the first bonding area BONA1 and the supply heat HEAT_IN transferred to the second bonding area BONA2 may be the same per unit area or unit volume, but the amount of heat ultimately transferred to the first bonding area BONA1 may be different from the amount of heat ultimately transferred to the second bonding area BONA2 due to the third emission heat HEAT_OUT22 of the package element PCD. For example, since the third emission heat HEAT_OUT22 is greater than the second emission heat HEAT_OUT21 and the first emission heat HEAT_OUT1, the amount of heat ultimately transferred to the first bonding area BONA1 may be less than the amount of heat ultimately transferred to the second bonding area BONA2.

Accordingly, the temperature of the general area GENA may be higher than the temperature of the package area PCKA. A temperature difference TEM_DIF may occur between the general area GENA and the package area PCKA due to the imbalance in the amount of ultimately transferred heat (see FIG. 16). A temperature TEM_BONA1 of the first bonding area BONA1 increases over time in a lower temperature range than a temperature TEM_BONA2 of the second bonding area BONA2.

The amount of heat transferred through the heat bonding device HBD and the support plate SUPP may be designed without considering the third emission heat HEAT_OUT22 and, in this case, sufficient heat may not be transferred to the first adhesive member AD1 corresponding to the first bonding area BONA1. Accordingly, poor adhesion PADP may occur at the first adhesive member AD1 corresponding to the first bonding area BONA1. The poor adhesion PADP may cause non-uniformity of the compression quality between the first bonding area BONA1 and the second bonding area BONA2 extending in the second direction DR2, and may further deteriorate the operating reliability of the display device.

To solve this problem, the amount of supply heat HEAT_IN supplied through the heat bonding device HBD and the amount of supply heat HEAT_IN transferred through the support plate SUPP may be increased. In the case of increasing the amount of supply heat HEAT_IN, the temperature of the first bonding area BONA1 may increase, but the temperature of the general area GENA where the heat dissipation plate HDP does not exist may also increase. Ultimately, heat whose amount is greater than the amount required for curing the first adhesive member AD1 may be supplied to the general area GENA where the heat dissipation plate HDP does not exist, and even in this case, the temperature imbalance may still exist between the first bonding area BONA1 and the second bonding area BONA2.

The present disclosure may provide a means for relieving the temperature imbalance between the general area GENA where the temperature is relatively high due to the absence of a component that performs the function of the heat dissipation plate HDP that emits heat and the package area PCKA where the temperature is relatively low due to the presence of the package element PCD that performs the function of the heat dissipation plate HDP. According to various embodiments disclosed in the present disclosure, the curing of the first adhesive member AD1 between the display panel PN and the interlayer insulating film ILINSF may become uniform regardless of the first bonding area BONA1 and the second bonding area BONA2. Accordingly, the compression quality of the bonding areas BONA1 and BONA2 may be improved, and the operating reliability of the display device may be improved.

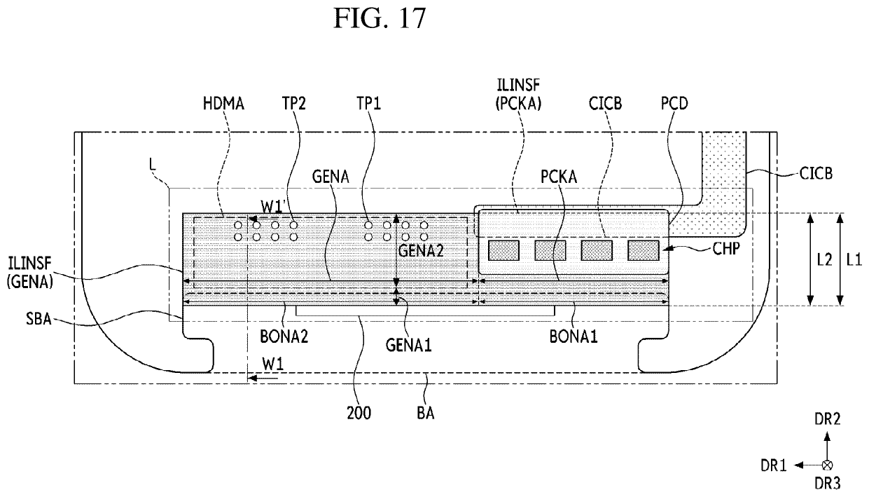

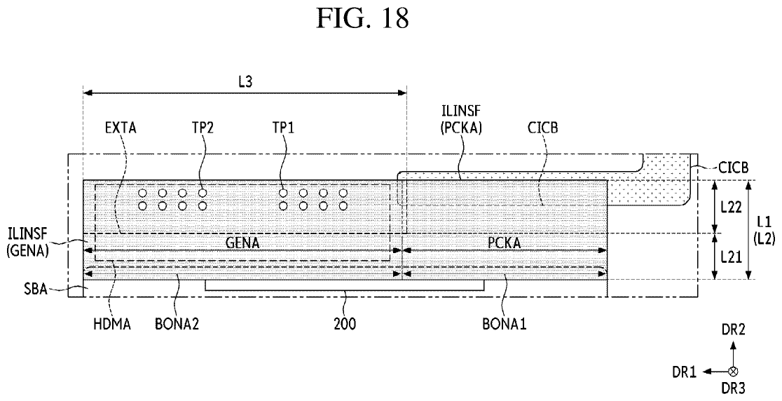

FIG. 17 is a plan view showing a display device according to a first embodiment of the present disclosure. FIG. 18 is a partially enlarged view showing area L of FIG. 17.

Referring to FIGS. 17 and 18, a bendable display device according to the first embodiment may include the interlayer insulating film ILINSF bonded to the sub-region SBA, and the package element PCD and the circuit board CICB electrically connected to the interlayer insulating film ILINSF.

The general area GENA of the interlayer insulating film ILINSF may have the second length L2 in the second direction DR2, and the package area PCKA may have the first length L1 in the second direction DR2. According to embodiments, the first length L1 and the second length L2 may be the same. The length of the general area GENA in the second direction DR2 may be extended to be the same as the first length L1. Accordingly, an extension area EXTA may be defined.

For example, the general area GENA formed to extend in the first direction DR1 and the second direction DR2 may include a first general area GENA1 extending in the first direction DR1 and a second general area GENA2 disposed in the second direction DR2 from the first general area GENA1. The second general area GENA2 may be defined to overlap the package element PCD in the first direction DR1. The second general area GENA2 may include the extension area EXTA. The length of the general area GENA in the second direction DR2 may be the same as the length of the package area PCKA in the second direction DR2.

The second general area GENA2 may include a heat sink (a heat dissipation member) area HDMA. For balance with the package element PCD that performs a heat dissipation function, the heat sink (a heat dissipation member) HDM may be formed in the heat sink area HDMA. To overcome the imbalance in the surface heat loss rate due to the area division of the interlayer insulating film ILINSF, the area of the interlayer insulating film ILINSF of the display device according to the first embodiment may increase by the area of the extension area EXTA. The extension area EXTA may have a third length L3 in the first direction DR1. The length of the extension area EXTA in the first direction DR1 may be the same as the length of the general area GENA in the first direction DR1. The length (the second length L2) of the general area GENA in the second direction DR2 may extend by a second sub-length L22. The second length L2 may be the sum of a first sub-length L21 and the second sub-length L22. The second general area GENA2 including the extension area EXTA may additionally include the heat sink area HDMA where the heat sink HDM is disposed in order to ensure the balance of the heat dissipation function.

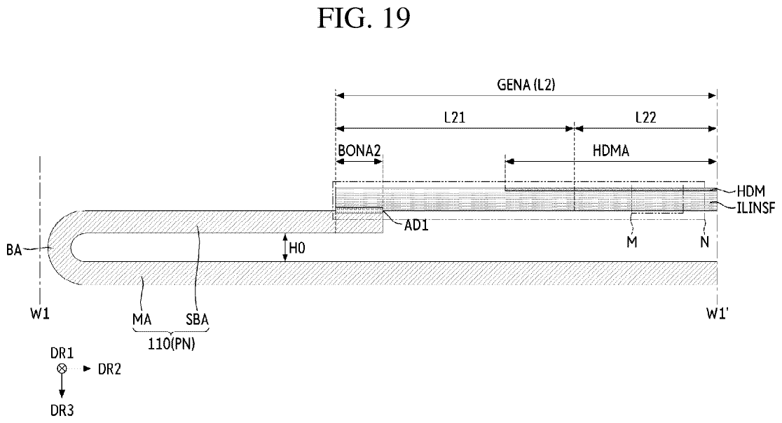

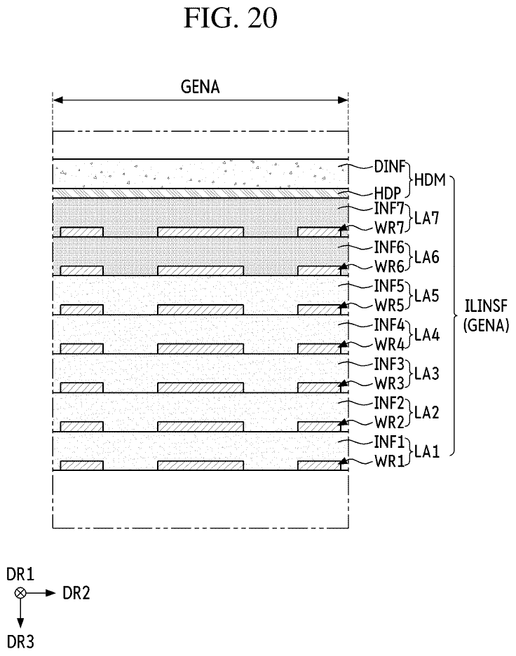

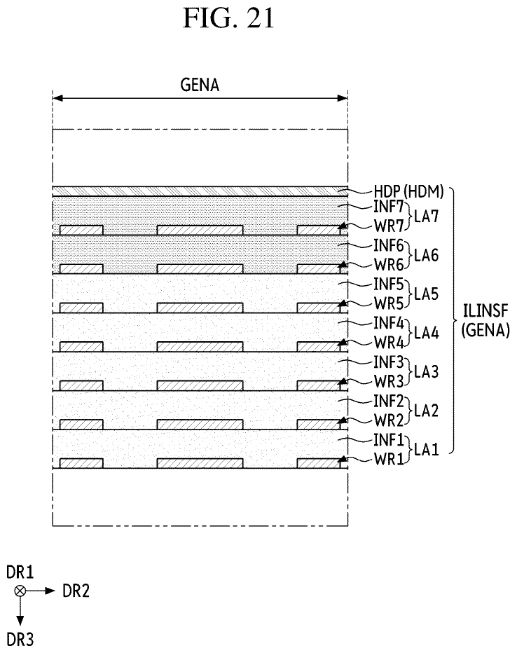

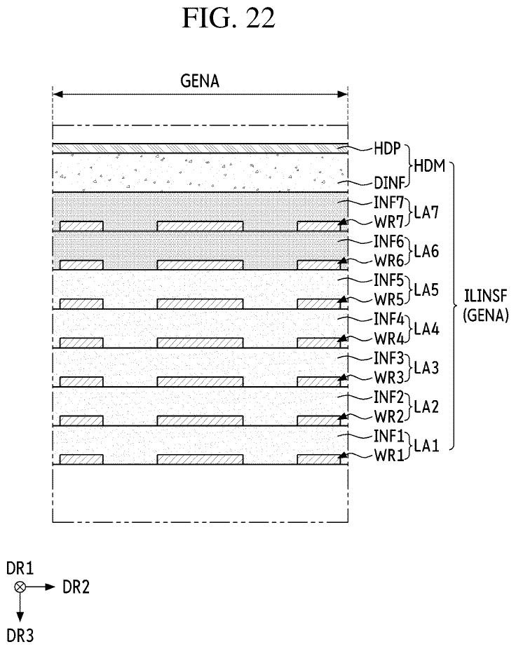

FIG. 19 is a cross-sectional view taken along line W1-W1′ of FIG. 17. FIG. 20 is a partially enlarged view showing area M of FIG. 19. FIG. 21 shows a first modified example of FIG. 20. FIG. 22 shows a second modified example of FIG. 20.

Referring to FIG. 19, the general area GENA extended by the second sub-length L22 may include the heat sink area HDMA whose length in the second direction DR2 is greater than the second sub-length L22. However, the embodiments of the present disclosure are not necessarily limited thereto. The length, area, and the like of the heat sink area HDMA may be variously modified in design in order to secure the balance with the heat dissipation function implemented (but not intended) from the package element PCD.

The heat sink area HDMA may include the heat sink HDM. Various embodiments of the present disclosure may provide various types of the heat sink HDM, which may be combined or coupled with each other and implemented in a display device.

Referring to FIG. 20, the interlayer insulating film ILINSF may include the heat sink HDM and the circuit wiring layers LA1, LA2, LA3, LA4, LA5, LA6, and LA7. The heat sink HDM may be disposed on the circuit wiring layers LA1, LA2, LA3, LA4, LA5, LA6, and LA7. The heat sink HDM may include a heat dissipation plate HDP disposed on the circuit wiring layers LA1, LA2, LA3, LA4, LA5, LA6, and LA7, and a dummy insulating film DINF covering the heat dissipation plate HDP. The heat dissipation plate HDP may be formed using a metal with high thermal conductivity. To increase the surface area per unit volume, the heat dissipation plate HDP may include a plurality of fin-shaped protrusions. For process efficiency, the heat dissipation plate HDP may include the same material as the first to seventh wires WR1, WR2, WR3, WR4, WR5, WR6, and WR7. In an embodiment, the heat dissipation HDP may include copper, but the embodiments of the present disclosure are not necessarily limited thereto.

Unlike the plurality of wires WR1, WR2, WR3, WR4, WR5, WR6, and WR7 of the circuit wiring layers LA1, LA2, LA3, LA4, LA5, LA6, and LA7, the heat dissipation plate HDP is not disposed to mediate electrical connection, and thus may not be electrically connected to the plurality of wires WR1, WR2, WR3, WR4, WR5, WR6, and WR7. In an embodiment, the heat dissipation plate HDP may be electrically isolated from the plurality of wires WR1, WR2, WR3, WR4, WR5, WR6, and WR7, but the embodiments of the present disclosure are not necessarily limited thereto.

In some embodiments, in order to expand the thermal path using the heat dissipation plate HDP, the heat dissipation plate HDP may be connected to the test pad described above. For example, the test pad described above may be disposed in the general area GENA, or may be disposed in the first bonding area or the second bonding area, as needed. According to the embodiments, the heat dissipation plate HDP may be connected to a test pad exposed to the ambient environment, thereby further expanding the thermal path.

The dummy insulating film DINF may cover the heat dissipation plate HDP. For process efficiency, the dummy insulating film DINF may include the same material as the first to seventh insulating films INF1, INF2, INF3, INF4, INF5, INF6, and INF7. In an embodiment, the dummy insulating film DINF may include an epoxy-based resin, but the embodiments of the present disclosure are not necessarily limited thereto.

According to the first embodiment, the heat sink HDM of the general area GENA includes the heat dissipation plate HDP electrically isolated from the first to seventh wires WR1, WR2, WR3, WR4, WR5, WR6, and WR7, and the dummy insulating film DINF introduced for process consistency with the plurality of wiring layers LA1, LA2, LA3, LA4, LA5, LA6, and LA7, and thus may improve the heat dissipation function of the general area GENA.

Referring to FIG. 21, the heat sink HDM may include only the heat dissipation plate HDP disposed on the circuit wiring layers LA1, LA2, LA3, LA4, LA5, LA6, and LA7. In this case, the heat sink HDM disposed in the general area GENA may be exposed to the ambient environment in the interlayer insulating film ILINSF. The heat dissipation plate HDP may be exposed to the ambient environment without an insulating film on the circuit wiring layers LA1, LA2, LA3, LA4, LA5, LA6, and LA7.

Referring to FIG. 22, the heat sink HDM may include the dummy insulating film DINF disposed on the circuit wiring layers LA1, LA2, LA3, LA4, LA5, LA6, and LA7, and the heat dissipation plate HDP disposed to be exposed to the ambient environment on the dummy insulating film DINF. The dummy insulating film DINF may be disposed between the circuit wiring layers LA1, LA2, LA3, LA4, LA5, LA6, and LA7 and the heat dissipation plate HDP.

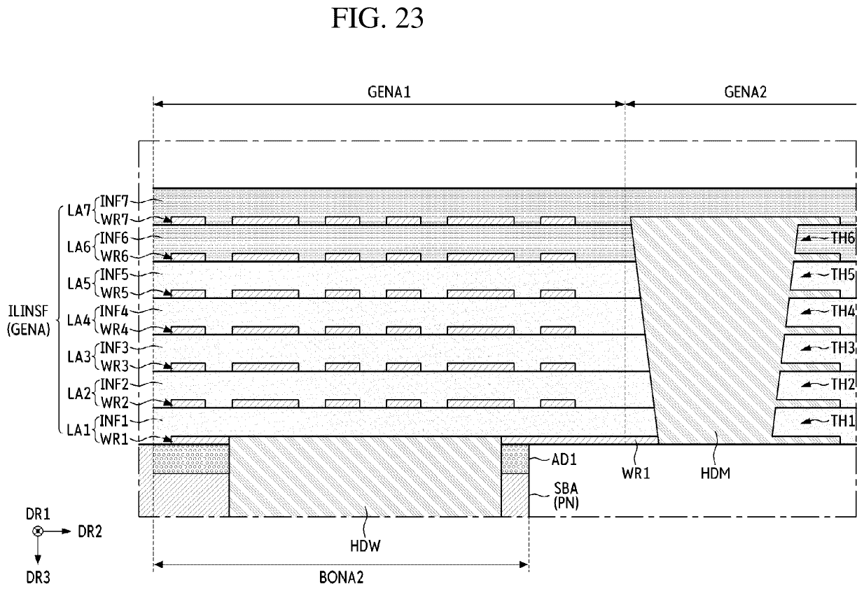

FIG. 23 is a partially enlarged view showing area N of FIG. 19.

Referring to FIG. 23, the heat sink HDM may extend in the second direction DR2 and the third direction DR3 (or thickness direction). In this case, the heat sink HDM may have a reverse tapered shape, but the embodiments of the present disclosure are not necessarily limited thereto.

The illustrated partially enlarged view may not correspond to that illustrated in FIG. 20. For example, in the illustrated embodiment, an additional layer using the heat dissipation plate HDP or the dummy insulating film DINF is not formed. The illustrated embodiment may include the heat sink HDM extending in the third direction DR3 (or thickness direction) through the first through holes TH1, TH2, TH3, TH4, TH5, and TH6 to secure a heat diffusion path from the second bonding area BONA2.

The heat sink HDM may be connected to a heat dissipation wire HDW through the first wire WR1 (or the first wire WR1 including a metal conductor), and the wire that connects the heat sink HDM to the heat dissipation wire HDW is not necessarily limited thereto. However, since the area to which heat is ultimately transferred is the first adhesive member AD1 of the second bonding area BONA2, and the first wire WR1 (or the first wire WR1 including a metal conductor) is the wire closest to the first adhesive member AD1, it may be preferable that the heat sink HDM is connected to the heat dissipation wire HDW through the first wire WR1 (or the first wire WR1 including a metal conductor) in terms of improvement of the heat dissipation function.

The heat sink HDM is connected to the heat dissipation wire HDW penetrating the second bonding area BONA2, and thus receives heat from the heat dissipation wire HDW and performs the heat dissipation function, so that the shorter distance between the wiring layer including “the wire that connects the heat sink HDM to the heat dissipation wire HDW” and the heat dissipation wire HDW may be more advantageous for heat dissipation. Preferably, the heat dissipation wire HDW and the heat sink HDM may be connected to each other through the first wire WR1 (or the first wire WR1 including a metal conductor) included in the first wiring layer LA1 closest to the heat dissipation wire HDW. At this time, the first wire WR1 (or the first wire WR1 including a metal conductor) that connects the heat sink HDM to the heat dissipation wire HDW provides a diffusion (or dissipation) path for heat applied to the second bonding area BONA2.

The heat transferred through the upper side and the lower side of the second bonding area BONA2 may be transferred to the heat sink HDM through the heat dissipation wire HDW, the first wire WR1 (or the first wire WR1 including a metal conductor). The heat sink HDM may fill all the first through hole TH1, the second through hole TH2, the third through hole TH3, the fourth through hole TH4, the fifth through hole TH5, and the sixth through hole TH6. In order to increase the surface area per unit volume, the heat sink HDM may include a plurality of protrusions (disposed in the first to seventh wiring layers LA1, LA2, LA3, LA4, LA5, LA6, and LA7) protruding in the second direction DR2.

The heat is dissipated (or diffused) to the second general area GENA2 where the heat sink HDM is disposed through the heat dissipation wire HDW, but the display panel PN connected to the heat dissipation wire HDW may also provide a heat dissipation function. Accordingly, the heat dissipation wire HDW may be connected to the display panel PN. In an embodiment, the heat dissipation wire HDW may be a ground wire utilized for dissipation of heat. The heat dissipation wire HDW may be connected to the ground wire disposed in the display panel PN to increase the diffusion (or, dissipation) of heat.

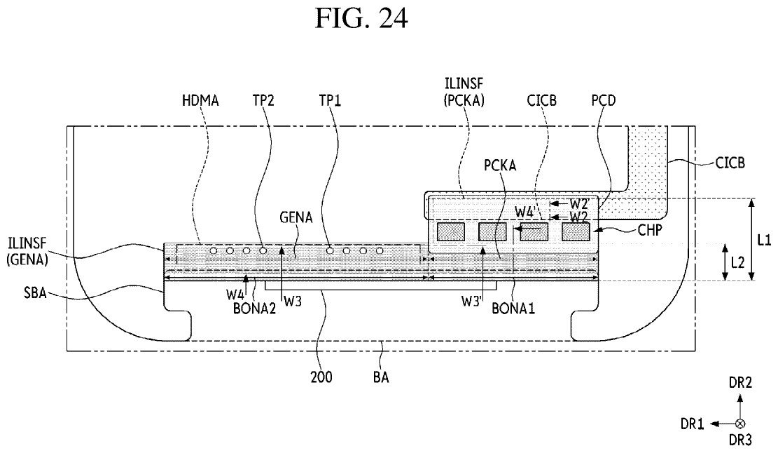

FIG. 24 is a plan view showing a display device according to an embodiment of the present disclosure.

Referring to FIG. 24, when the general area GENA of the interlayer insulating film ILINSF does not extend in the second direction DR2, the heat sink area HDMA may be disposed in the general area GENA that does not overlap the second bonding area BONA2.

The display device according to an embodiment forms the heat sink area HDMA in the general area GENA that does not overlap the second bonding area BONA2 in order to extend the thermal path. Although the area of the heat sink area HDMA becomes relatively small compared to the first embodiment, the heat dissipation performance may be balanced by additionally providing a heat dissipation film HDF, as will be described later.

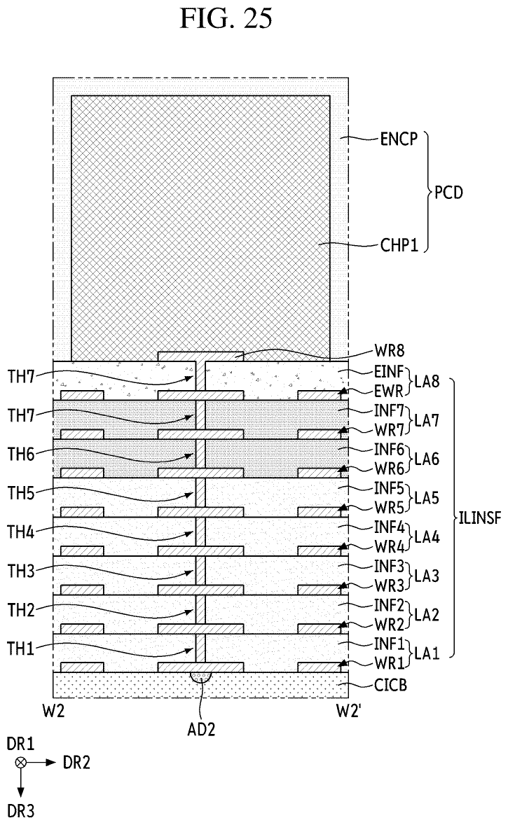

FIG. 25 is a cross-sectional view taken along line W2-W2′ of FIG. 24.

Referring to FIGS. 20, 22, and 25, when the heat sink HDM is formed to include the dummy insulating film DINF, the interlayer insulating film ILINSF may further include an eighth wiring layer LA8 disposed on the circuit wiring layers LA1, LA2, LA3, LA4, LA5, LA6, and LA7 in order to uniformly adjust the thickness of the interlayer insulating film ILINSF in the first direction DR1. The eighth wiring layer LA8 may include an extension insulating film EINF formed to correspond to the dummy insulating film DINF. The eighth wiring layer LA8 may further include an extension wire EWR in order to ensure the balance of the electrical connection relationship in the interlayer insulating film ILINSF. The eighth wire WR8 may be disposed on the eighth wiring layer LA8.

Since a relative temperature drop occurs in the package area PCKA including the first bonding area BONA1, the heat dissipation plate HDP needs to be electrically isolated from the extension wire EWR. If the heat dissipation plate HDP is electrically connected to the extension wire EWR, heat applied to the package area PCKA may be dissipated or diffused through the heat sink HDM including the heat dissipation plate HDP. In this case, since a temperature drop may occur not only in the general area GENA but also in the package area PCKA, the extension wire EWR disposed in the package area PCKA according to an embodiment may be electrically isolated from the heat sink HDM including the heat dissipation plate HDP.

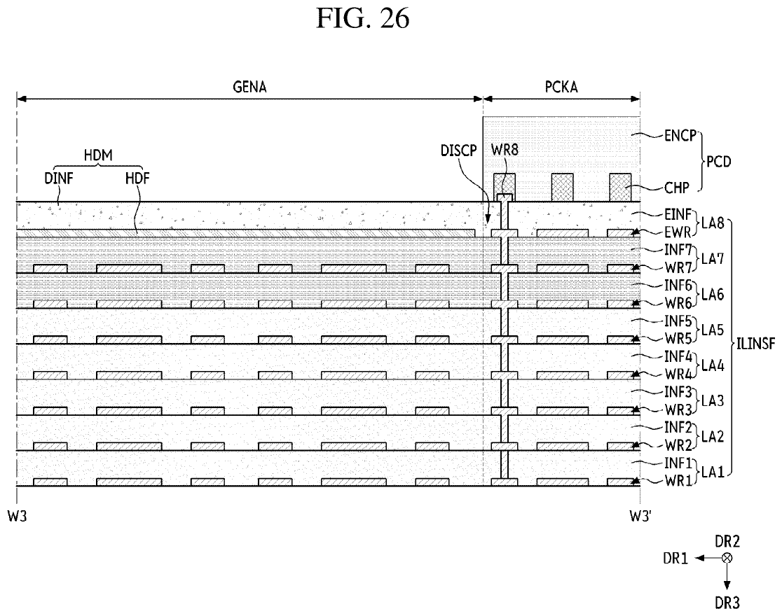

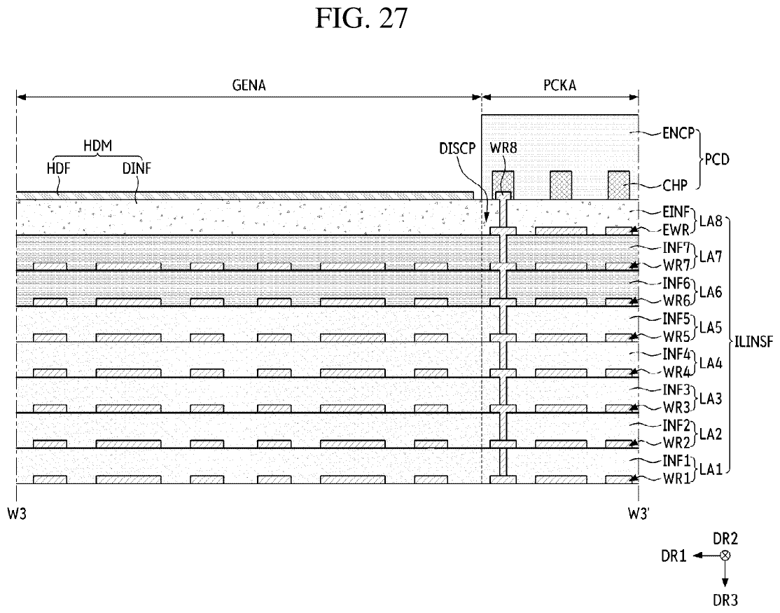

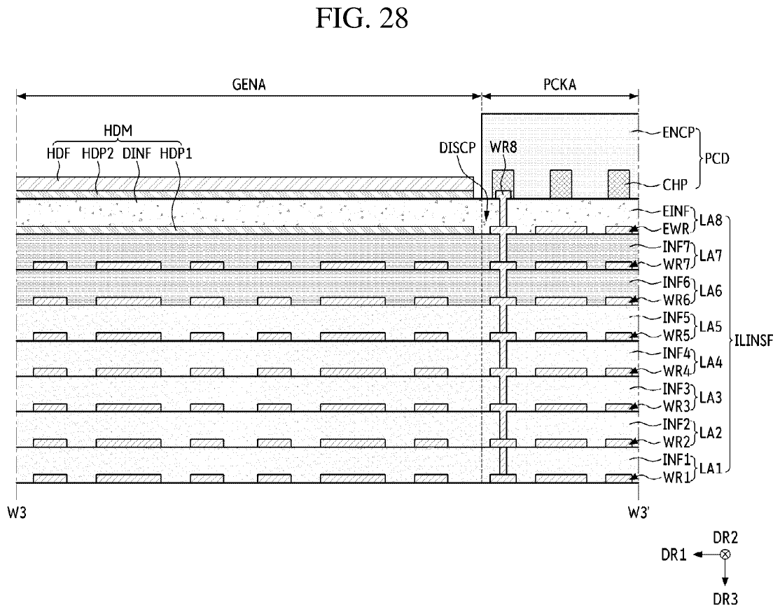

FIG. 26 is a cross-sectional view taken along line W3-W3′ of FIG. 24. FIG. 27 shows a first modified example of FIG. 26. FIG. 28 shows a second modified example of FIG. 26.

Referring to FIGS. 26 to 28, the heat sink HDM of the general area GENA may include the heat dissipation plate HDP and the dummy insulating film DINF, and the package area PCKA may include the extension insulating film EINF and the extension wire EWR corresponding to the dummy insulating film DINF. As described above, since the heat dissipation function through the heat sink HDM disposed in the general area GENA needs to occur only in the general area GENA, a disconnected portion DISCP may be formed between the extension wire EWR and the heat dissipation plate HDP. The disconnected portion DISCP may electrically isolate the extension wire EWR and the heat dissipation plate HDP from each other.

Referring to FIG. 28, the heat sink HDM may further include the first heat dissipation plate HDP1, the dummy insulating film DINF disposed on the first heat dissipation plate HDP1, the second heat dissipation plate HDP2 disposed on the dummy insulating film DINF, and the heat dissipation film HDF disposed on the second heat dissipation plate HDP2. When the heat dissipation plate HDP is exposed to the ambient environment, as in the case where the second heat dissipation plate HDP2 is disposed on the dummy insulating film DINF, the heat dissipation film HDF may be disposed on the second heat dissipation plate HDP2 to extend the thermal path. The heat dissipation film HDF may be formed using a material with high thermal conductivity, such as copper, aluminum, or silicon.

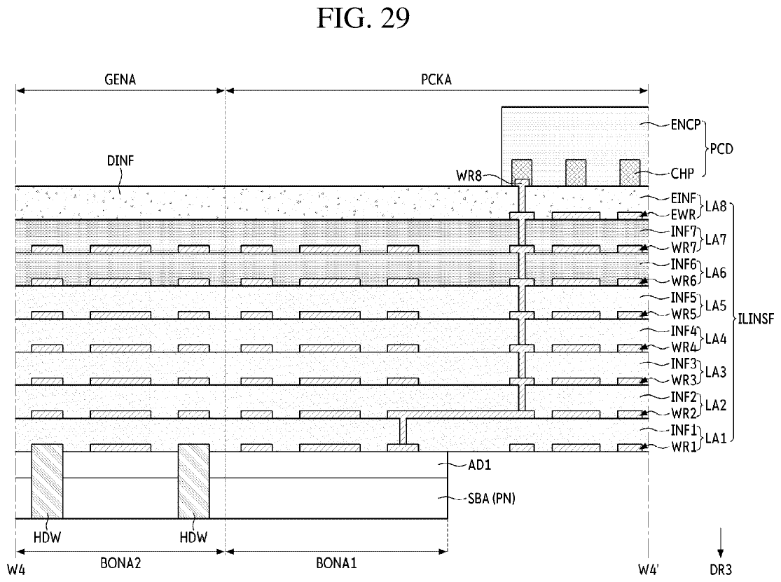

FIG. 29 is a cross-sectional view taken along line W4-W4′ of FIG. 24.

Referring to FIG. 29, the heat dissipation wire HDW may be electrically isolated from wires disposed in the package area PCKA. As described above, the heat dissipation function through the heat sink HDM disposed in the general area GENA needs to occur only in the general area GENA, and the heat dissipation wire HDW is a component introduced to enhance the heat dissipation function while being connected to the heat sink HDM, so that it is required to maintain a state in which the heat dissipation wire HDW is electrically isolated from the wires in the package area PCKA.

As disclosed in the various embodiments described above, the present disclosure discloses various technical solutions for additionally securing a heat dissipation path by providing the heat sink in the display device. The various embodiments that increase the heat dissipation path are not necessarily limited to those in the drawings of the present disclosure, and may be combined or coupled with each other to derive other embodiments.

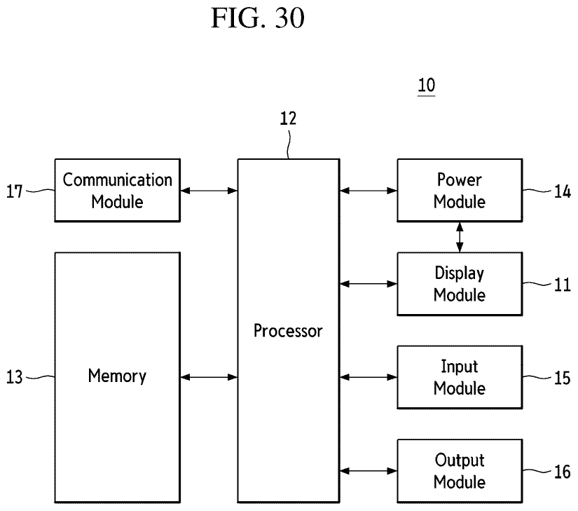

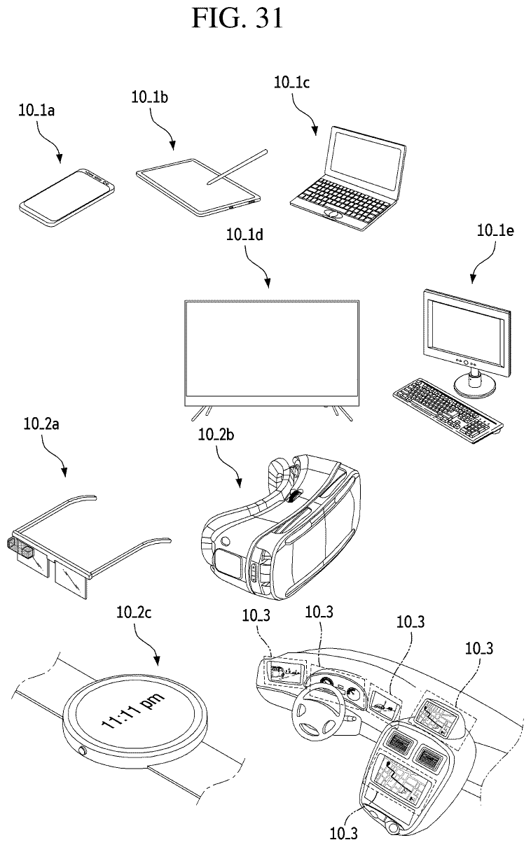

FIG. 30 is a block diagram of an electronic device according to an embodiment of the present disclosure. FIG. 31 is schematic views of electronic devices according to various embodiments of the present disclosure.

Referring to FIG. 30, the electronic device 10, according to an embodiment, may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device. The power module 14 may include a power conversion module. The power conversion module may convert the power supplied by the power supply module to generate power required for the operation of the electronic device 10.

At least one of the components of the electronic device 10 described above may be included in the display device according to the embodiments described above. Further, some of individual modules functionally included in one module may be included in the display device and some others may be provided separately from the display device. For example, the display device may include the display module 11, while the processor 12, the memory 13 and the power module 14 may be provided as other devices in the electronic device, other than the display device.

The electronic device 10 may further include an input module 15, a non-image output module 16, and/or a communication module 17.

The input module 15 may provide input information to the processor 12 and/or the display module 11. The input module 15 may include not only physical buttons, a keyboard, and a microphone, but also various sensor modules. Examples of the sensor module may include a touch sensor, a pressure sensor, a proximity sensor, a position sensor, a digitizer, a motion recognition sensor, a camera sensor, a light receiving sensor, a photoelectric conversion sensor, and a temperature sensor, as well as biometric sensors such as a blood pressure sensor, a blood glucose sensor, an electrocardiogram sensor, and a heart rate sensor.

The non-image output module 16 may receive information other than images from the processor 12 and provide the information to a user. Examples of the non-image output module 16 may include an audio module, a haptic module, and a light emitting module, and may further include other function modules specific to the electronic device (e.g., a cooling module of a refrigerator).

The communication module 17 may be a module configured to transmit and receive information between the electronic device 10 and an external device, and may include a receiver and a transmitter. The communication module 17 may include various types of wireless communication modules such as a mobile communication module, a Wi-Fi module, and a Bluetooth module, or various types of wired communication modules.

Referring to FIG. 31, various electronic devices to which the display device according to the embodiments of the present disclosure is applied may include electronic devices for displaying images, such as a smartphone 10_1a, a tablet computer 10_1b, a laptop/notebook computer 10_1c, a television (TV) 10_1d, a computer monitor 10_1e, and the like. In addition, various electronic devices to which the display devices according to the embodiments of the present disclosure are applied may include a wearable electronic device including a display module such as smart glasses 10_2a, a head mounted display 10_2b, and a smart watch 10_2c, a vehicle electronic device 10_3 including a display module such as an instrument panel of a vehicle, a center fascia, a center information display (CID) provided on a dashboard, or a room mirror display, and the like.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary in all respects and are not necessarily intended to be limiting.

What is claimed is:

1. A display device, comprising:
a display panel comprising a main region extending in a first direction and a second direction intersecting the first direction, and a sub-region protruding in the second direction from one side of the main region;
an interlayer insulating film attached to the sub-region;
a package element disposed on the interlayer insulating film; and
a circuit board attached to the interlayer insulating film,
wherein the interlayer insulating film comprises a package area and a general area disposed in the first direction from the package area,
wherein the package element is disposed in the package area,
wherein each of the general area and the package area comprises a circuit wiring layer electrically connecting the sub-region, the package element, and the circuit board to each other, and
wherein the general area further comprises a heat sink.

2. The display device of claim 1, wherein the circuit wiring layer comprises a first wiring layer comprising a first wire and a first insulating film covering the first wire.

3. The display device of claim 2, wherein the circuit wiring layer further comprises a second wiring layer comprising a second wire disposed on the first insulating film and a second insulating film covering the second wire.

4. The display device of claim 2, wherein the heat sink is disposed on the circuit wiring layer.

5. The display device of claim 2, wherein the heat sink comprises a heat dissipation plate disposed on the circuit wiring layer.

6. The display device of claim 5, wherein the heat sink further comprises a dummy insulating film disposed on the circuit wiring layer.

7. The display device of claim 6, wherein the package area further comprises an extension insulating film disposed in a same layer as the dummy insulating film and disposed on the circuit wiring layer.

8. The display device of claim 7, wherein the heat dissipation plate is electrically isolated from the first wire of the package area.

9. The display device of claim 7, wherein the package area further comprises an extension wire disposed in a same layer as the heat dissipation plate, between the circuit wiring layer and the extension insulating film, and electrically connected to the package element, and
wherein the heat dissipation plate is electrically isolated from the extension wire.

10. The display device of claim 5, wherein the heat dissipation plate comprises a same material as the first wire.

11. The display device of claim 7, wherein the extension insulating film comprises a same material as the dummy insulating film.

12. The display device of claim 5, wherein the heat sink further comprises a heat dissipation film disposed on the heat dissipation plate.

13. The display device of claim 3, wherein the general area comprises:
a first general area; and
a second general area disposed in the second direction from the first general area and overlapping the package element in the first direction,
wherein the package area has a first length in the second direction,
wherein the general area has a second length in the second direction,
wherein the first length is equal to the second length, and
wherein the second general area comprises the heat sink.

14. The display device of claim 13, wherein the heat sink further comprises a metal conductor electrically connected to a heat dissipation wire disposed in an area where the general area and the sub-region overlap in a thickness direction of the display panel, and
wherein the heat sink is disposed in a first through hole penetrating the first insulating film and a second through hole penetrating the second insulating film.

15. The display device of claim 14, wherein the metal conductor is connected to the heat dissipation wire through the first wire.

16. An electronic device, comprising:
a processor configured to provide an image signal;
a display module configured to receive the image signal from the processor and display an image; and
a power module configured to supply power to the display module,
wherein the display module comprises:
a display panel comprising a main region extending in a first direction and a second direction intersecting the first direction, and a sub-region protruding in the second direction from one side of the main region;
an interlayer insulating film attached to the sub-region;
a package element disposed on the interlayer insulating film; and
a circuit board attached to the interlayer insulating film,
wherein the interlayer insulating film comprises a package area and a general area disposed in the first direction from the package area,
wherein the package element is disposed in the package area,
wherein each of the general area and the package area comprises a circuit wiring layer electrically connecting the sub-region, the package element, and the circuit board, and
wherein the general area further comprises a heat sink.

17. The electronic device of claim 16, wherein the circuit wiring layer comprises:
a first wiring layer comprising a first wire and a first insulating film covering the first wire; and
a second wiring layer comprising a second wire disposed on the first insulating film and a second insulating film covering the second wire.

18. The electronic device of claim 17, wherein the heat sink comprises:
a heat dissipation plate disposed on the circuit wiring layer; and
a dummy insulating film disposed on the circuit wiring layer, wherein the package area further comprises:
an extension insulating film disposed in a same layer as the dummy insulating film and disposed on the circuit wiring layer; and
an extension wire disposed in a same layer as the heat dissipation plate between the circuit wiring layer and the extension insulating film and electrically connected to the package element, and
wherein the heat dissipation plate is electrically isolated from the extension wire.

19. The electronic device of claim 18, wherein the heat dissipation plate comprises a same material as the first wire.

20. The electronic device of claim 17, wherein the general area comprises:
a first general area; and
a second general area disposed in the second direction from the first general area and overlapping the package element in the first direction,
wherein the package area has a first length in the second direction,
wherein the general area has a second length in the second direction,
wherein the first length is equal to the second length, and
wherein the second general area comprises a heat sink.
